(19) United States
(12) Patent Application Publication
(10) Pub. No.: US 2021/0223341 A1
(43) Pub. Date: Jul. 22, 2021

(54) SOLID-STATE MRI AS A NONINVASIVE ALTERNATIVE TO COMPUTED TOMOGRAPHY (CT)

(71) Applicant: THE TRUSTEES OF THE UNIVERSITY OF PENNSYLVANIA, Philadelphia, PA (US)

(72) Inventors: Felix W. WEHRLI, Bala Cynwyd, PA (US); Scott P. BARTLETT, Philadelphia, PA (US); Hyunyeol LEE, Philadelphia, PA (US); Hee Kwon SONG, Moorestown, NJ (US); Xia ZHAO, Sichuan (CN)

(21) Appl. No.: 15/734,087

(22) PCT Filed: May 31, 2019
(86) PCT No.: PCT/US2019/034997

§ 371 Date: Dec. 1, 2020

Related U.S. Application Data
(60) Provisional application No. 62/679,453, filed on Jun. 1, 2018.

(51) Int. Cl. G01R 33/48; G01R 33/56; G01R 33/561; G01R 33/565; G01R 33/567

(52) U.S. Cl. CPC G01R 33/4816; G01R 33/4826; G01R 33/5608; G01R 33/5676; G01R 33/5619; G01R 33/56509; G01R 33/5607

(57) ABSTRACT

The present disclosure provides systems, apparatuses, and methods for generating images of the human body by solid-state magnetic resonance imaging. An example method can comprise receiving first imaging data at two or more echo times taken with a first radiofrequency configuration, receiving second imaging data at two or more echo times taken with a second radiofrequency configuration. An example method can comprise generating, based on at least the first imaging data and the second imaging data, two or more k-space datasets. An example method can comprise generating, based on at least the two or more k-space datasets, one or more images. The one or more images can comprise different image contrast.

### CROSS-REFERENCE TO RELATED APPLICATIONS

This application claims the benefit of and priority to U.S. Patent Application No. 62/679,453 (filed Jun. 1, 2018), which application is hereby incorporated herein by reference in its entirety for any and all purposes.

### TECHNICAL FIELD

The invention relates to solid-state MRI and more particularly to systems and methods for using MRI as a non-invasive alternative to CT.

### BACKGROUND

Computed tomography (CT) enables 3D visualization of cortical bone structures with high spatial resolution, and thus has been the gold standard method for evaluation and diagnosis of craniofacial skeletal pathologies. However, ionizing radiation, and in particular, repeated scanning with this modality in pre- and post-surgery, is of concern when applied to infants and young children. As an alternative, Eley K A, Mcintyre A G, Watt-Smith S R, Golding S J. “Black bone” MRI: a partial flip angle technique for radiation reduction in craniofacial imaging. Br J Radiol. 2012; 85(1011):272-278 proposed a ‘black-bone’ MRI method in which low flip-angle 3D GRE imaging yields proton-density weighted contrast, thereby facilitating discrimination between bone and soft-tissue. However, in this approach bone appears with near background intensity (i.e. ‘black’) due to very short T₂ relaxation times and relatively low proton density, making it challenging to distinguish between bone and air. Thus, improvements are needed.

### SUMMARY

Computed tomography (CT) imaging is the imaging modality of choice for 3D visualization of bone. However, there is growing concern about repeated exposure to ionizing radiation, in particular during infancy, for instance, in patients with craniosynostosis pre- and post-surgery. Solid-state MRI methods via ultrashort echo time (UTE) or zero TE (ZTE), capable of imaging spins with very short T₂ relaxation times, are thus promising alternatives. In the present disclosure, a dual-RF, dual-echo, 3D UTE sequence is provided using view-sharing to minimize scan time. Images are reconstructed by combining long- and short-RF, first and second echoes, yielding soft-tissue suppressed skull images at 1.1 mm isotropic resolution in 6 minutes scan time in a human skull ex vivo and test subjects in vivo. 3D renderings display the relevant craniofacial skeleton similar to CT. The present disclosure also includes a system including a processor that executes stored instructions for executing the steps of the method.

Conventional MRI is not suited for imaging bone, which appears with near background intensity due to very short T2 relaxation times and relatively low proton density (˜20% by volume), thus bone signal is difficult to distinguish from air. Recent advances in solid-state MRI allow capture of the short-T2 signals in cortical bone, originating predominantly from water tightly bound to the collagen matrix (T2, 200-300 μs) while suppressing the signal from soft-tissue protons (T2, 50-100 ms).

The present disclosure provides a method for generating three-dimensional images of the skull by solid-state magnetic resonance imaging, involving the steps of data acquisition, reconstruction and processing, as means to guide surgical intervention. An early version of the method with some, but not all of the planned features, has been reduced to practice by the inventors in a human skull as well as in live human subjects in comparison to CT.

In one embodiment a dual-RF sequence using rectangular RF pulses differing in duration but of equal nominal flip angle, each generating two echoes, is utilized. Soft-tissue signal is minimized and bone signal is enhanced by suitably combining echoes from the two datasets. The significance of a near 10-fold reduction in scan time is in the method's target application, i.e. children, who are less adherent than adults. However, the systems and methods provided herein may be used on various parts of the body and on various patients. After appropriately combining images, residual soft-tissue signal is removed via post-processing and three-dimensional anatomic renderings of the skull are obtained.

The above and other characteristic features of the invention will be apparent from the following detailed description of the invention.

### BRIEF DESCRIPTION OF THE DRAWINGS

The present disclosure contains at least one drawing/photograph executed in color. Copies of this patent or patent application publication with color drawing(s)/photograph(s) will be provided by the Office upon request and payment of the necessary fee.

The present application is further understood when read in conjunction with the appended drawings. In the drawings:

FIG. 1A is a diagram of the view-shared, dual-RF, dual-echo 3D UTE pulse sequence, in which RF1 (short˜40 μs) and RF² (long˜520 μs) are alternately played out and four independent signals are produced: ECHO11, ECHO12, ECHO21, and ECHO22.

FIG. 1B is a schematic of k-space construction with view-sharing between ECHO11 and ECHO21 (k1) and between ECHO12 and ECHO22 (k2). Note that varying gradients (radial view angles) on a TR basis make it possible to employ the view-sharing approach, thus enabling shortened scan time. Note also that the central portion of k1 and k2 is composed only of ECHO11 and ECHO22 to maximally differentiate bone signals between two corresponding images.

FIG. 2 shows three sets of images, acquired using dual-RF 3D UTE pulse sequence with full sampling (top) and with view-sharing (bottom): I1, I2, and Ibone. Note that the view-sharing method (bottom), when compared with the parent technique (top), halves scan time without visible loss of image quality. Note further bone voxels, inner table of cranium, and foam pad in Ibone images (right column).

FIG. 3 is a flow diagram of an advanced reconstruction pipeline: Estimation of S and φ is achieved using oversampled central k-space data, starting with initialization: k=0, I₁⁰=0, I₂⁰=0, followed by:

$$\begin{matrix}{I}_{1}^{k + 1} = {min}_{{I}_{1}} \frac{1}{2} {‖ {y}_{1} - {ℱ}_{N U} ( {SI}_{1} ) ‖}_{2}^{2} + λ {‖ {I}_{1} - {I}_{2}^{k} {e}^{- i ϕ} ‖}_{1} and & ( step 1 ) \\ {I}_{2}^{k + 1} = {min}_{{I}_{2}} \frac{1}{2} {‖ {y}_{2} - {ℱ}_{N U} ( {SI}_{2} ) ‖}_{2}^{2} + λ {‖ {I}_{2} - {I}_{1}^{k + 1} {e}^{i ϕ} ‖}_{1} , & ( step 2 )\end{matrix}$$

with steps 1 and 2 repeated until convergence is reached.

FIG. 4 shows three sets of image reconstructed using the algorithm in FIG. 3 on data acquired using the dual-RF 3D pulse sequence with imaging times of 3 (top) and 1.5 (bottom) minutes. Note that the sparsity-constrained reconstruction preserves image qualities in both I₁ and I₂, leading to bone voxels highlighted without visual loss of signals in the normalized difference images.

FIG. 5 illustrates a comparison of ex vivo human skull images between CT (top) and the proposed MRI method (bottom). Magnitude images in three orthogonal planes (left) are shown along with 3D renderings for three different views (right).

FIG. 6 shows seven sets of images in two test subjects (male 44 y and female 50 y): I1, I2, Ibone, and 3D rendering in frontal, lateral, posterior, and superior views. In subject 2, cranial coronal sutures on both sides are well visualized in the posterior view of 3D rendering.

FIG. 7A shows a graph comparing MR-based and CT-based measurements.

FIG. 7B shows a graph comparing MR-based and direct measurements.

FIG. 7C shows a graph comparing CT-based and direct measurements.

FIG. 8 shows a comparison of healthy adult subject MR scan obtained using 20 channel versus 32 channel head coil.

FIG. 9 shows a comparison of MR and CT images of subject 1, a 45 year old male.

FIG. 10 shows a comparison of MR and CT images of subject 2, a 26 year old female.

FIG. 11 shows a comparison of MR and CT images of subject 3, a 27 year old male.

FIG. 12 shows a comparison of MR and CT images of subject 4, a 27 year old female.

FIG. 13 shows a comparison of MR and CT images of subject 5, a 35 year old male.

FIG. 14 shows a comparison of MR and CT images of a pediatric subject 16 years of age.

FIG. 15A shows a diagram of the dual-RF and dual-echo 3D UTE pulse sequence.

FIG. 15B shows comparison of view-orders in distributing projections (number: 4096) in 3D k-space between conventional (left) and the proposed (right) methods.

FIG. 16A is a flowchart shown an example method for motion correction of an image.

FIG. 16B is a flowchart showing another example method for motion correction of an image.

FIG. 17A shows an exemplary time-course of COM reflecting four occurrences of the subject's head motion.

FIG. 17B shows five exemplary sets of GRE image corresponding to each motion state.

FIG. 17C shows exemplary correction of k-space datasets using the estimated rigid-motion parameters.

FIG. 17D shows exemplary images with and without motion correction.

FIG. 18A shows exemplary images reconstructed directly using inverse NUFFT.

FIG. 18B show exemplary images reconstructed using motion correction as disclosed herein followed by sparse reconstruction.

FIG. 19A shows an exemplary comparison of imaging techniques.

FIG. 19B shows exemplary models reconstructed using imaging techniques.

FIG. 20 shows exemplary image distortion due to motion.

FIG. 21 shows exemplary image correction.

FIG. 22 shows exemplary sampling of signals.

FIG. 23 shows exemplary Dual-RF UTE.

FIG. 24 shows exemplary motion correction steps.

FIG. 25 shows exemplary motion detection and COM derivation.

FIG. 26A shows exemplary conventional trajectory.

FIG. 26B shows exemplary golden-means trajectory.

FIG. 27A shows exemplary translations and sensitivity.

FIG. 27B shows exemplary rotations and sensitivity.

FIG. 28 shows exemplary motion estimation.

FIG. 29 shows exemplary motion correction.

FIG. 30A shows exemplary center of mass data.

FIG. 30B shows exemplary signal intensity.

FIG. 30C shows an exemplary comparison of images.

FIG. 31 shows exemplary trajectory calibration.

FIG. 32A shows exemplary UTE.

FIG. 32B shows exemplary GRE.

FIG. 32C shows an exemplary comparison of images.

### DETAILED DESCRIPTION OF ILLUSTRATIVE EMBODIMENTS

### Conventional MRI Sequences

One approach to isolate the signal from bone (or rather the lack thereof) is isotropic 3D gradient-echo imaging performed at very low flip angle on the order of 1-3°, which results in proton-density-weighted soft-tissue contrast, ideally allowing single-threshold based segmentation. This method has been termed “black-bone MRI” (BB-MRI) since bone in the source images appears with essentially background intensity. 3D surface-rendered images created after eliminating soft-tissue signal were found to yield images suitable for performing anatomical measurements of the skull, including visualization of normal and prematurely fused cranial sutures. However, distinction between air and bone (sinuses, for example), is a significant source of error in all segmentation approaches evaluated. Gradient-echo images are also prone to susceptibility artifacts near the air-tissue boundaries, which can lead to erroneous assignment to background voxels during segmentation, clearly unacceptable to the craniofacial surgeon.

### Solid-State MRI

A rather different approach aims to capture the signal from bone while attenuating or suppressing the signal from soft-tissue protons. Cortical bone contains about 20% water by volume, predominantly in the form of water hydrogen bonded to collagen, with a smaller fraction residing in the pores of the lacuno-canalicular system. Bound water has a T₂ relaxation time on the order of 250-400 μs. Detection of these protons may require that the following conditions to be met: 1) the time at which k-space center is scanned (typically referred to as ‘echo time’ even though an FID is collected) and, 2) the duration of the RF pulse, both have to be significantly shorter than T₂. Failure to satisfy these conditions results in damping of the magnetization response.

Two major classes of pulsed excitation techniques have emerged meeting the above requirements. The first is referred to as ultra-short TE (UTE), the second as zero-TE (ZTE) MRI. It is understood though that both classes of short-T₂ imaging have to meet the second condition for excitation. Long-T₂ suppression is typically achieved by means of T₂-selective inversion pulses, echo subtraction or by exploiting the differential nutation of short and long-T₂ spins. The latter can also be combined with echo subtraction.

BB-MRI, while attractive because of the simplicity of image acquisition (short-TR/TE 3D gradient echo), is hampered by its failure to distinguish bone from air. Other conventional methods require segmentation separating out background and soft-tissue from bone, which is complicated by the need for bias field correction (a problem also inherent to the BB approach), and the overlap of the histogram comprising bone and brain tissue. Simple dual-echo UTE or ZTE with echo subtraction, for example, inadequately suppresses soft-tissue. All inversion-preparation based UTE or ZTE approaches are impractical as they result in excessive scan times even with significant under sampling.

### Proposed Approach

The present disclosure provides excitation and processing strategies that exploit the dynamics of transverse relaxation both during and after the RF pulse. While the attenuation of the signal following excitation is straightforward, resulting in an exponential reduction in M_{xy} with increasing TE, the losses during the RF pulse have a somewhat more complicated dependence on T₂, pulse duration i, and RF field amplitude B₁. For rectangular pulses (as described herein), the response to the RF pulse can be expressed for the normalized longitudinal and transverse magnetization as:

$${f}_{z} = {e}^{\frac{- τ}{2 {T}_{2}^{*}}} [ cos \sqrt{{( γ {B}_{1} τ )}^{2} - {( \frac{τ}{2 {T}_{2}^{*}} )}^{2}} + \frac{τ}{2 {T}_{2}^{*}} sinc ( \sqrt{{( γ {B}_{1} τ )}^{2} - {( \frac{τ}{2 {T}_{2}^{*}} )}^{2}} ) ] , \\ {f}_{x y} = γ {B}_{1} τ {e}^{\frac{- τ}{2 {T}_{2}^{*}}} sinc ( \sqrt{{( γ {B}_{1} τ )}^{2} - {( \frac{τ}{2 {T}_{2}^{*}} )}^{2}} ) \qquad [ 1 a , b ]$$

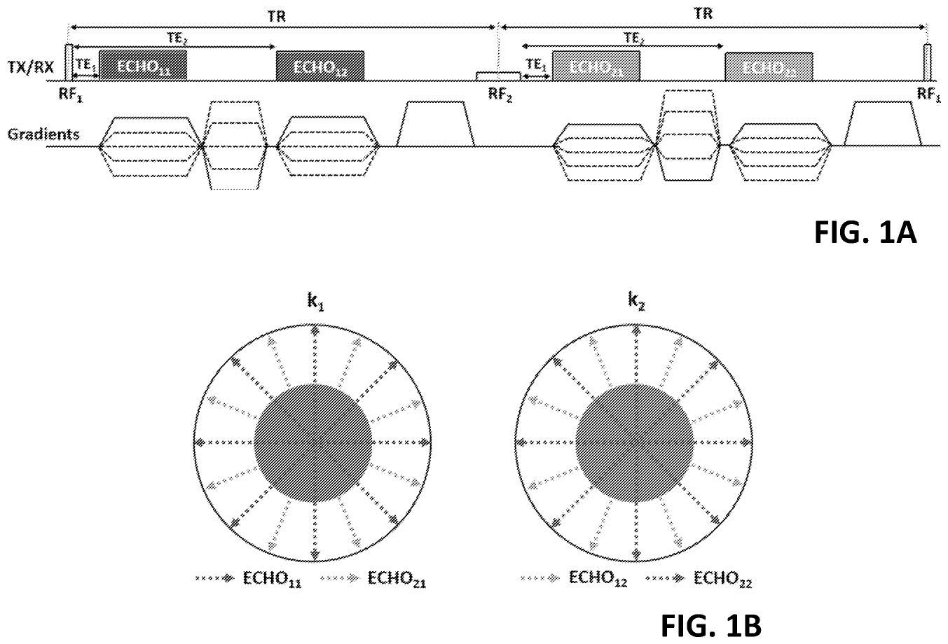

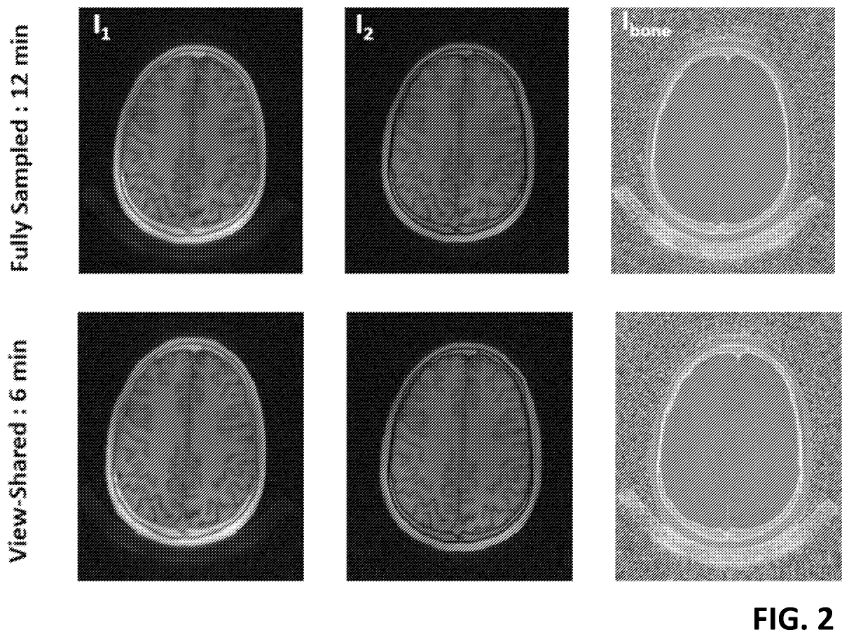

Eqs 1a,b revert to cos(γB₁τ) and sin(γB₁τ) for τ<<T₂. By collecting data so that each radial spoke is sampled with short and long pulse durations (τ<50 μs and τ˜500 μs, respectively), and each is read out twice at short and long echo times (TE<100 μs and ˜1-2 ms, respectively), four data sets may be created. The short and long RF pulses have equal nominal flip angle, therefore differing in their amplitude. The greatest soft-tissue attenuation and optimal bone signal retention is achieved by taking the difference between short pulse, short TE (SP-UTE) and long-pulse, long pulse duration (LP-LTE) data so, in principle, it suffices to acquire only one echo each. Typically, the data are processed by dividing the difference by the sum of the two images. This has the advantage of correcting for bias due to spatial variation in signal reception or RF inhomogeneity. However, as two acquisitions of each k-space line are used, scan time is doubled. This can be avoided without incurring an image quality penalty by sharing views from the additional echoes (see e.g., FIGS. 1 and 2) currently achieving whole-skull coverage at 1 mm³ voxel size at 3T in 6 minutes (instead of 12 minutes without view sharing). Further shortening of scan time may be achieved in combination with compressed sensing as described below.

### Example Methods

FIG. 1A shows a diagram of the dual-RF, dual-echo 3D UTE pulse sequence, wherein two RF pulses (RF1, RF2) differing in duration and amplitude (but equal nominal nutation angle) are alternately applied in successive TR periods along the pulse train while within each TR two echoes are acquired at short and long TEs (TE1, TE2), respectively, from the beginning of gradient ramp-up. Thus, four echoes are obtained: ECHO11, ECHO12, ECHO21, and ECHO22. Here, the subscripts represent RF and TE indices in this order (FIG. 1A). Bone proton magnetization (pertaining to bound water), due to its very short T2 relaxation time, exhibits a substantial level of signal decay during the relatively long duration of RF2, while soft-tissue retains nearly the same level of signal intensities over all echoes. Thus, subtraction of ECHO22 from ECHO11, when compared to the difference between ECHO11 and ECHO12, further enhances bone contrast. In the proposed method, two additional signals, ECHO12 and ECHO21, can be collected while radial view angles are varied every TR (e.g., instead of every two TRs), leading to a two-fold increase in imaging efficiency via view-sharing. Echoes at the same TEs are combined to produce two k-space sets (k1, k2), in which central regions are composed only of ECHO11 and ECHO22 views to retain the highest and lowest bone signals, respectively, thereby maximizing bone signal specificity upon subtraction.

Data were acquired in a human skull ex vivo and two subjects in vivo at 3 T field strength (Siemens Prisma) using the proposed dual-RF, dual-echo 3D UTE sequence. Imaging parameters: TR/TE1/TE2=7/0.06/2.46 ms, RF1/RF2 durations=40/520 μs, flip angle=12°, matrix size=256, field-of-view=280 mm3, voxel size=1.1 mm isotropic, number of radial spokes=25,000, and scan time=6 min. Additionally, a calibration scan was performed to determine gradient timing delays and subsequent correction for k-space trajectory errors. Images for k1 (I1) and k2 (I2) were reconstructed using a conventional gridding algorithm. Bone images (Ibone) with minimal soft-tissue contamination were then obtained as I_{bone} (I1−I2)/(I₁+I₂). Given the three sets of images (I1, I2, Ibone), segmentation of bone voxels was performed using ITK-SNAP (e.g., but other segmentation approaches may be used) in a semi-automatic fashion, leading to 3D renderings of the skull. For comparison, a CT scan was also performed in the human cadaveric skull with 1 mm isotropic resolution.

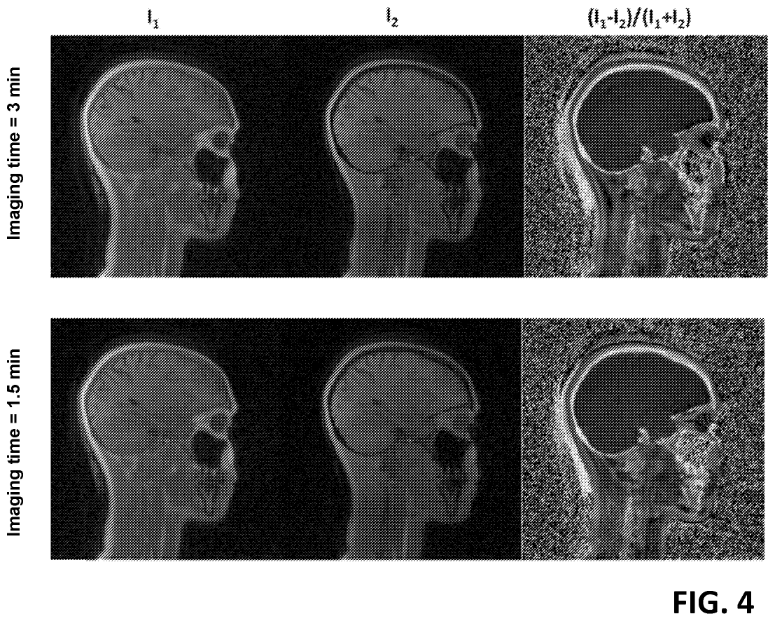

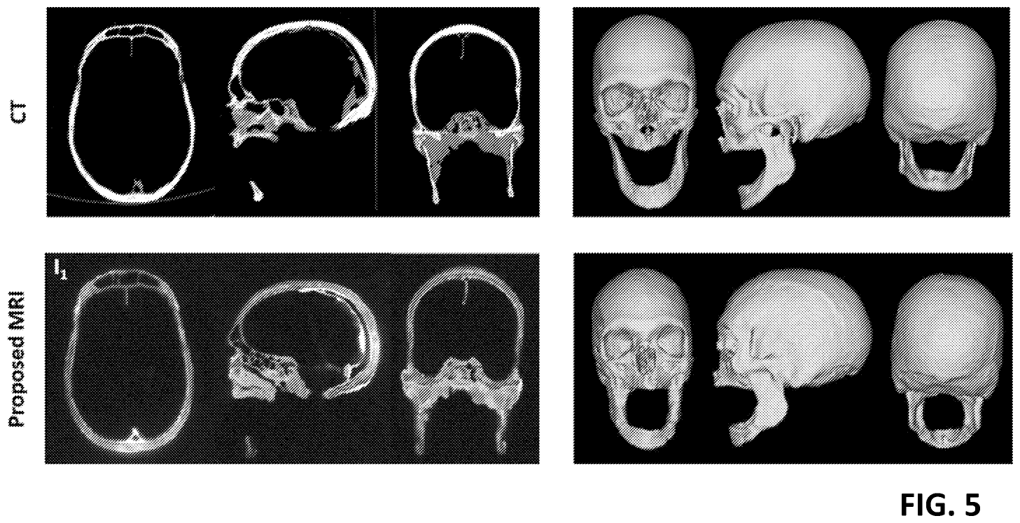

FIG. 2 shows the effectiveness of the proposed view-sharing approach in accelerating the imaging time by a factor of two. Compared with full sampling, the view-sharing scheme exhibits no appreciable loss in image quality. FIG. 5 compares CT with the proposed MRI method on cadaveric human skull images, along with corresponding 3D renderings. Compared to CT, the 3D rendered images obtained with the speed-enhanced technique maintain most features over the entire head (e.g., zygomatic arch), except for appearance of some artifacts in the mandibular region. FIG. 4 displays in vivo head images in two subjects: I1, I2, Ibone, and 3D rendering. In Ibone images, bone voxels as well as inner table of the cranium are clearly visualized, and cranial and spinal bone structures are well depicted in the 3D renderings. Still, some voxels erroneously included or excluded in the renderings will require further improvement in post-processing.

The proposed methods achieve high-resolution images of cranial bone structures, allowing for 3D renditions of the skull while interfering soft-tissue structures (intra- and extracranial) are eliminated. The target application focuses on craniometric measurements and visualization of skull and facial bones in surgical planning and post-surgical follow-up but the method is not limited to the skull bone architecture and should be equally suited in other applications requiring accurate rendition of portions of the skeleton elsewhere in the body. The proposed method incorporates solid-state MR imaging with signal sharing, bone-specifying signal processing, and sparsity-constrained image reconstruction, as described below for each compartment.

The proposed method comprises collection of image data at more than one echo time and radiofrequency configuration. Collected imaging signals at multiple echo times with variable radiofrequency pulse-lengths are shared to construct two or more k-space datasets differing in the levels of bone signals (due to very short T2 of the nuclei of interest) but having nearly identical signal strengths of intra- and extra-cranial components (due to relatively long T2 thereof), enabling a reduction of scan time by two or more as compared to conventional approaches. An example of such embodiment is shown in FIGS. 1A-B, wherein two k-space signal areas are composed of signals at two echo times (one very short (˜40 μs) and one relatively long (˜2 ms), both following short (˜40 μs) and long (˜520 μs) radiofrequency pulses, respectively.

The proposed method may comprise bone-specific signal processing. For example, signal intensities for bone vary with individual images reconstructed from each k-space, while those for soft tissues are nearly constant, thus allowing enhancing bone contrast by taking a temporal derivative on reconstructed images with different echo times. Further, the derivative is normalized by a temporal integration of all images so as to remove voxel-specific constants such as water proton density, receiver coil sensitivity, and transmit radiofrequency field variations. Exemplary images generated from the schematic in FIG. TA are shown in FIG. 2 (bottom) in comparison to those from the parent method (e.g., as shown in FIG. 2 (top)).

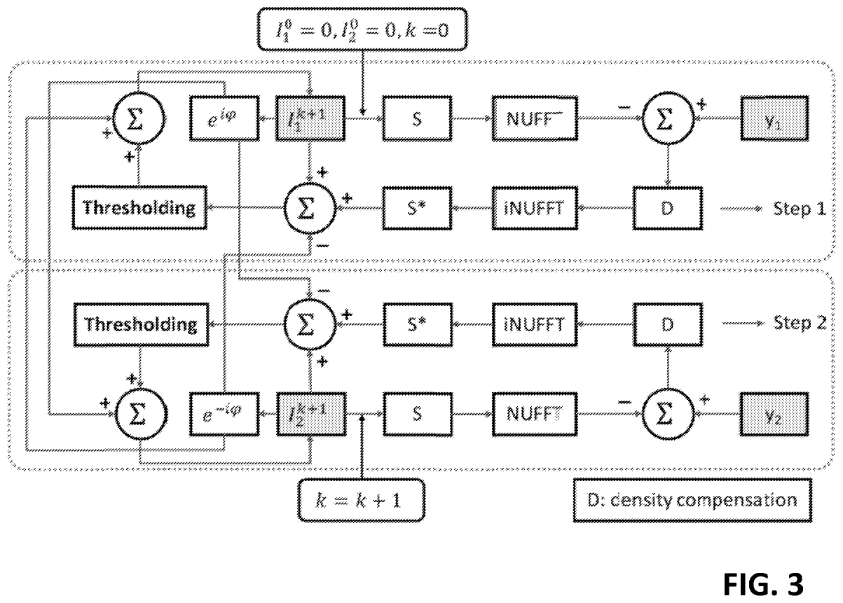

The proposed method may comprise sparsity-constrained image reconstruction. For example, without loss of generality, for the two image signal acquisitions in FIG. 1A, the following sparse signal recovery problem can be formulated:

$${min}_{{I}_{1} , {I}_{2}} \frac{1}{2} {‖ {y}_{1} - {ℱ}_{N U} ( {SI}_{1} ) ‖}_{2}^{2} + \frac{1}{2} {‖ {y}_{2} - {ℱ}_{N U} ( {SI}_{2} ) ‖}_{2}^{2} + λ {‖ {I}_{1} - {I}_{2} {e}^{- i ϕ} ‖}_{1} \qquad ( 2 )$$

where y₁ and y₂ are the measured complex data in k-space for first and second echo times, I₁ and I₂ are complex images for first and second echo times, [symbol] _{NU} is the non-uniform Fourier transformation, S is the receiver coil sensitivity matrix, λ is the regularization parameter that balances data consistency with residual sparsity, φ is the phase accrual during the time between the first and second echo times, and ∥⋅∥₁ and ∥⋅∥₂ are l₁- and l₂-norms. It is noted that as I₁ and I₂ are complex, phase correction with (in the last term in Eq. (2) is essential, failure to do so potentially disrupts residual sparsity. Both S and p are spatially smooth and thus can be estimated using over-sampled central low spatial-frequency data. The solutions (I₁, I₂) can be found by employing an alternating minimization approach. Specifically, Eq. (2) is split into two sub-problems with respect to I₁ and I₂. Subsequently, numerical optimization methods, including but not limited to iterative soft-thresholding or non-linear conjugate gradient, are applied to solve each problem. The two solutions are iteratively updated until convergence is reached. In the preferred embodiment of the method, algorithm based on iterative soft-thresholding in combination with a parallel imaging is being used (e.g., as shown in FIG. 3). The resulting images are shown in FIG. 4 for two different sampling rates (leading to imaging times of 3 and 1.5 minutes) suggest the new method to be able of achieving high-speed craniofacial MR imaging without visual artifacts or blurring.

FIG. 5 illustrates a comparison of ex vivo human skull images between CT (e.g., shown in the top row) and the proposed MRI method (e.g., as shown in the bottom row). Magnitude images in three orthogonal planes (e.g., as shown in left column) are shown along with 3D renderings for three different views (e.g., as shown in right column).

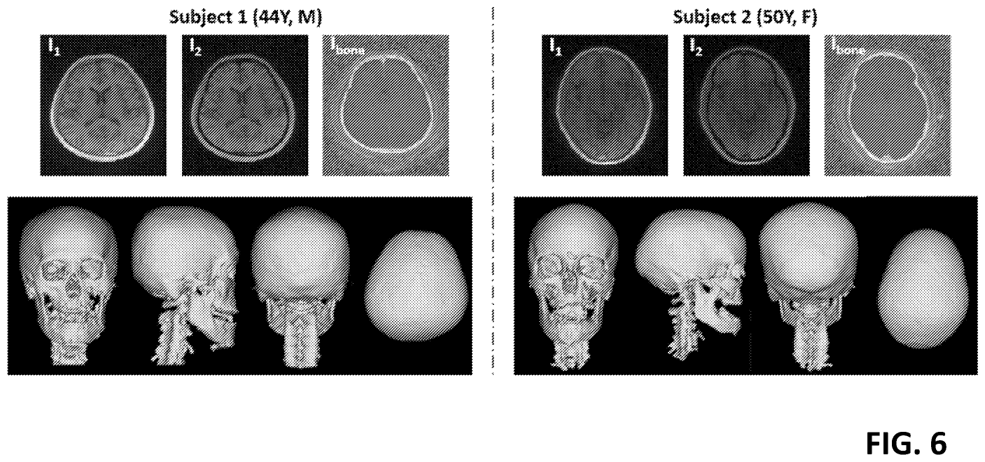

FIG. 6 shows seven sets of images in two test subjects (male 44 y and female 50 y): I1, I2, Ibone, and 3D rendering in frontal, lateral, posterior, and superior views. In subject 2, cranial coronal sutures on both sides are well visualized in the posterior view of 3D rendering.

The proposed MRI-based skull imaging methods and systems, along with optimized post-processing, provide a non-invasive alternative to CT for visualization of craniofacial architecture.

### Additional Analysis and Results

The technology in this disclosure utilizes a rapid bone MRI method involving a 3D DUal-RAdiofrequency aNd Dual-Echo (DURANDE) UTE pulse sequence along with bone-selective image reconstruction. Imaging time was reduced by a factor of two by taking advantage of data redundancy both during signal acquisition and image reconstruction.

This disclosure addresses, inter alia, the clinical translatability of the bone-selective MR method for obtaining 3D renderings of the human skull, and compare it to the current gold-standard of thin-slice CT imaging. In vitro and in vivo studies were performed at 3T to evaluate the proposed technique in achieving high-resolution 3D skull images that can be used for qualitative evaluation of craniofacial structures and quantitative anatomic measurements.

Comparison of CT and Bone-Selective MRI for 3D Rendering of Human Cadaver Skull.

The objectives of this study were to 1) produce 3D renderings of the human skull using the bone-selective MRI technique 2) compare biometric accuracy of anatomical measurements obtained from CT-based and MRI-based 3D renderings of the human cadaver skull.

Example methods are described as follows.

Imaging technique: As previously explained, FIG. 1A shows the diagram of a dual-RF, dual-echo 3D UTE pulse sequence. The dual-RF, dual-echo 3D UTE pulse sequence can comprise an RF 1 (short 40 μs) and an RF² (long˜520 μs) signal that are alternately played out. Four independent signals can be produced: ECHO11, ECHO12, ECHO21, and ECHO22.

Two RF pulses differing in duration and amplitude are alternately applied in successive repetition time (TR) along the pulse train. Within each TR, two echoes are acquired. Acquisition of the first echo starts at the ramp-up of the encoding gradient (TE₁), allowing for capture of signals with very short lifetimes (bone), while that of the second starts after a longer delay (TE₂). In total, four echoes are obtained: ECHO₁₁ (RF₁TE₁), ECHO₁₂ (RF₁TE₂), ECHO₂₁ (RF₂TE₁), and ECHO₂₂ (RF₂TE₂). During reconstruction, ECHO₁₁ is combined with ECHO₂₁ (Image 1) and ECHO₁₂ is combined with ECHO₂₂ (Image 2) (e.g., see FIG. 1B). Image 2 is then subtracted from Image 1 to yield the final bone-selective image.

Data acquisition/processing: Scans for this study were completed at a tertiary university hospital. The pulse sequence described above was applied at 3 T field strength (Siemens Prisma, Erlangen, Germany) with 32-channel head coil. The skull was placed in a direct horizontal position conventionally used for imaging of the head.

Imaging parameters: TR/TE₁/TE₂=7/0.06/2.46 ms, RF₁/RF₂ durations=40/520 μs, flip angle=12°, matrix size=256³¹, field-of-view=28031 mm³, voxel size=1.1 mm isotropic, number of radial spokes=25,000, and scan time=6 min.

Semi-automatic segmentation of bone voxels was performed using the classification feature of ITK-SNAP³². The user draws examples of tissue classes in the image, using a paint brush tool to label each class example with a corresponding color. A machine learning algorithm uses these examples to assign classifications to the rest of the image. In this study, the user drew examples of bone tissue, soft tissue and air. After segmentation, the 3D model of the skull was generated using the ITK-SNAP software, and exported as an STL file.

For comparison, a CT scan (GE Medical Systems, Milwaukee, Ill.) was also performed of the human cadaver skull with 1 mm slice thickness. Segmentation of the CT scan was performed using preset bone CT thresholds on the Mimics software (Materialise®, Ghent, Belgium), the current standard protocol at CHOP for craniofacial imaging analysis. After segmentation, the 3D model was automatically generated using the Mimics software and exported as an STL file.

The biometric accuracy was assessed by measuring eight anatomic distances in both CT- and MRI-based 3D renderings of the human cadaver skull. The STL files of the 3D renderings were uploaded to 3-Matic (Materialise®, Ghent, Belgium) software and anatomic distances were measured using the ruler tool. These distances were compared with those directly measured on the cadaver skull, with calipers (resolution 1 mm). Each distance was measured 20 times by a single assessor (RZ) and the mean value calculated. The eight anatomic distances are as follows: 1) Maximum craniocaudal aperture of the right orbit, 2) Maximum craniocaudal aperture of the left orbit, 3) Maximum height of the mandible from chin point in the midline, 4) Maximum cranial length, 5) Maximum cranial width, 6) Maximum height of piriform aperture, 7) Distance between lateral most aspect of zygomatic arches, 8) Maxilla width.

Given that ITK-SNAP assumes a voxel size of 1 mm, the MR measurements were scaled by 1.0938, to account for actual voxel size of 1.0938 mm (280 mm (field-of-view)/256 (matrix size)). In some implementations, scaling may not be necessary or other scaling amounts may be used.

Lin's Concordance Correlation test was applied to assess agreement between mean measurements obtained from MR-based and CT based 3D skull renderings, cadaver and MR-based rendering, and cadaver and CT-based rendering.

This experiment was repeated after a two week time interval to provide a second sample. Between scan sessions, the skull was stored in a −34 deg. C. freezer designated for fresh cadaver specimens.

Results are shown in FIG. 5. As explained, FIG. 5 compares cadaver skull images obtained from CT and the proposed MR method, along with corresponding 3D renderings. The subtraction of Image 2 (ECHO₁₂ combined with ECHO₂₂) from Image 1 (ECHO₁₁ combined with ECHO21) yielded an image with enhanced bone contrast. Compared to CT, the 3D rendered images maintain most features over the entire head (e.g., zygomatic arch), except for the appearance of some artifacts in the mandibular region.

Table 1 presents the mean measurements from Sample 1, obtained from each modality.

TABLE 1

| Mean Measurement | Modality | | |
|---|---|---|---|
| (cm ± SD) | MR | CT | Cadaver |
| Cranial length | 19.9 ± 0.2 | 19.4 ± 0.1 | 18.6 ± 0.1 |
| Cranial width | 13.9 ± 0.1 | 13.9 ± 0.1 | 13.2 ± 0.1 |
| L orbit height | 3.7 ± 0.1 | 3.5 ± 0.1 | 3.5 ± 0.1 |
| R orbit height | 3.6 ± 0.1 | 3.4 ± 0.1 | 3.4 ± 0.1 |
| Piriform aperture | 3.3 ± 0.1 | 3.7 ± 0.0 | 3.6 ± 0.1 |
| Inter-zygomatic arch width | 12.5 ± 0.1 | 12.2 ± 0.1 | 12.3 ± 0.1 |
| Mandibular height | 2.6 ± 0.1 | 2.7 ± 0.1 | 2.7 ± 0.1 |
| Maxilla width | 5.0 ± 0.1 | 5.0 ± 0.1 | 4.9 ± 0.1 |

Table 2 presents the mean absolute and percent differences when comparing the three modalities.

TABLE 2

| | Mean Difference | Mean Percent Difference |
|---|---|---|
| Comparison | (cm ± SD) | (% ± SD) |
| MR vs CT | 0.1 ± 0.3 | −0.2 ± 5.9 |
| MR vs Cadaver | 0.3 ± 0.5 | 1.4 ± 6.3 |
| CT vs Cadaver | 0.2 ± 0.4 | 1.6 ± 2.3 |

Table 3 presents the mean measurements from Sample 2, obtained from each modality

TABLE 3

| Mean Measurement | Modality | | |
|---|---|---|---|
| (cm) | MR | CT | Cadaver |
| Cranial length | 20.4 ± 0.2 | 18.5 ± 0.2 | 18.3 ± 0.4 |
| Cranial width | 14.0 ± 0.1 | 13.3 ± 0.1 | 13.2 ± 0.1 |
| L orbit height | 3.6 ± 0.1 | 3.6 ± 0.1 | 3.6 ± 0.1 |
| R orbit height | 3.5 ± 0.1 | 3.7 ± 0.1 | 3.5 ± 0.1 |
| Piriform aperture | 3.3 ± 0.1 | 3.6 ± 0.1 | 3.7 ± 0.1 |
| Inter-zygomatic arch width | 13.0 ± 0.0 | 12.7 ± 0.1 | 12.2 ± 0.1 |
| Mandibular height | 2.5 ± 0.1 | 2.5 ± 0.1 | 2.6 ± 0.1 |
| Maxilla width | 5.2 ± 0.1 | 5.3 ± 0.1 | 4.8 ± 0.1 |

Table 4 presents the mean absolute and percent differences when comparing the three modalities.

TABLE 4

| | Mean Difference | Mean Percent Difference |
|---|---|---|
| Comparison | (cm ± SD) | (% ± SD) |
| MR vs CT | 0.3 ± 0.7 | 0.0 ± 6.0 |
| MR vs Cadaver | 0.4 ± 0.8 | 1.8 ± 7.2 |
| CT vs Cadaver | 0.2 ± 0.2 | 1.8 ± 4.5 |

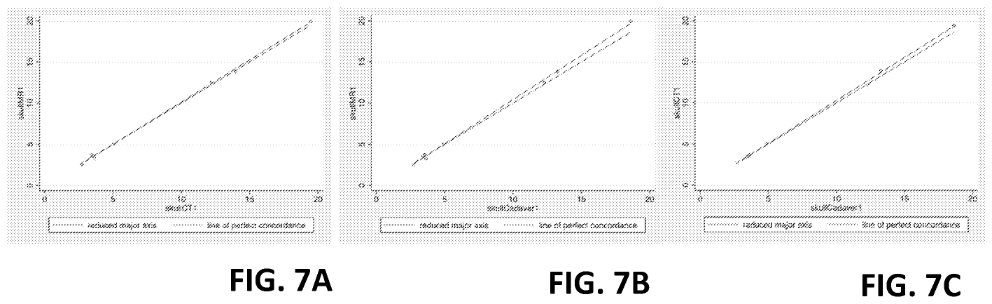

FIGS. 7A-C presents a graphical display of the Sample 1 correlations between MR-based and CT-based measurements (e.g., as shown in FIG. 7A), MR-based and direct measurements (e.g., as shown in FIG. 7B), and CT-based and direct measurements (e.g., as shown in FIG. 7C).

Table 5 presents the Sample 1 Lin's Concordance Correlation Coefficients for these modalities.

TABLE 5

| | Lin's | |
|---|---|---|
| | Concordance | |
| | Correlation | |
| Comparison | Coefficient | 95% CI |
| MR vs CT | 0.999 | 0.997-1.000 |
| MR vs Cadaver | 0.996 | 0.991-1.000 |
| CT vs Cadaver | 0.998 | 0.995-1.000 |

Table 6 presents the Sample 2 Lin's Concordance Correlation Coefficients for these modalities.

TABLE 6

| | Lin's | |
|---|---|---|
| | Concordance | |
| | Correlation | |
| Comparison | Coefficient | 95% CI |
| MR vs CT | 0.992 | 0.986-0.999 |
| MR vs Cadaver | 0.989 | 0.980-0.999 |
| CT vs Cadaver | 0.999 | 0.997-1.001 |

Discussion: The disclosed dual-RF dual-echo 3D UTE imaging technique produces high-resolution bone-specified images of a human cadaver skull within a clinically feasible imaging time (6 minutes), leading to clear visualization of craniofacial skeletal structures. Comparison of eight anatomic distance measurements obtained from MR and CT images yielded a mean absolute difference of 1 mm and percent difference of −0.2%. The concordance coefficients of 0.999 (Sample 1) and 0.992 (Sample 2) correspond to a substantial strength of agreement between MR and CT³³. These results show the reliability of the MR method when compared to CT. Mean percent difference of MR versus direct cadaver measurements (Sample 1: 1.4±6.3%, Sample 2: 1.8±7.2%) was similar to mean percent difference of CT versus direct cadaver measurements (Sample 1: 1.6±2.3%, Sample 2: 1.8±4.5%).

Segmentation of MR images was performed in a semi-automatic fashion with ITK-SNAP. This included the user first identifying bone vs air vs soft tissue voxels in order to train the machine learning algorithm. The segmentation process was aided by the removal of soft tissue from the cadaver skull prior to scanning.

Comparison of CT and Bone-Selective MRI for 3D Rendering of Healthy Adult Human Subject Skulls.

The objectives of this study were to 1) produce 3D skull renderings of healthy adult human subjects, using a novel bone-selective MRI technique 2) compare visualization of cranial sutures and the biometric accuracy of anatomical measurements obtained from CT-based and MRI-based 3D renderings.

Example methods used in this study are described as follows.

Imaging technique: The bone-selective MR pulse sequence was previously described herein.

Data acquisition/processing: MR imaging parameters were as previously described in Section 2. No contrast or sedation was used for any subject. All scans were completed at CHOP, and therefore the scanners used were different from those used for the cadaver skull study described above.

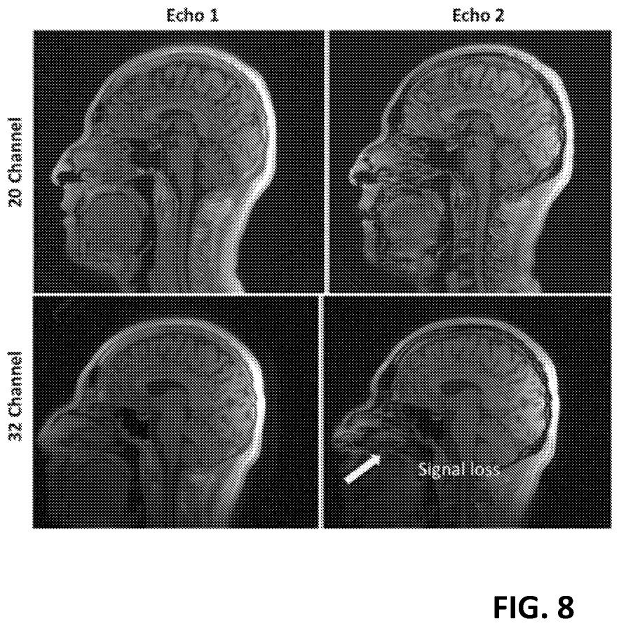

FIG. 8 shows a comparison of healthy adult subject MR scan obtained using 20 channel versus 32 channel head coil. All subjects were imaged in the same MRI scanner (Siemens Prisma, Erlangen, Germany) with a 20-channel head coil. Preliminary adult human subject scans indicated greater signal loss from facial structures in scans obtained with 32-channel head coil compared to scans obtained with 20-channel head coil (e.g., as shown in FIG. 8).

Each subject additionally underwent a non-investigational head CT scan, as a gold standard comparison to the bone-selective MR scan. The scan protocol specified a 0.75 mm slice thickness with low-dose radiation, lower than the standard head CT (CTDIvol of 7 or less). The 0.75 mm slice thickness is the CHOP clinical standard for 3D head CT scans used for craniofacial imaging and surgical planning. A single scanner (GE Medical Systems, Milwaukee, Ill.) was used for all scans.

3D rendering of the skull from MR scans and CT scans, as well as comparison of craniometric measurements, were performed as described herein.

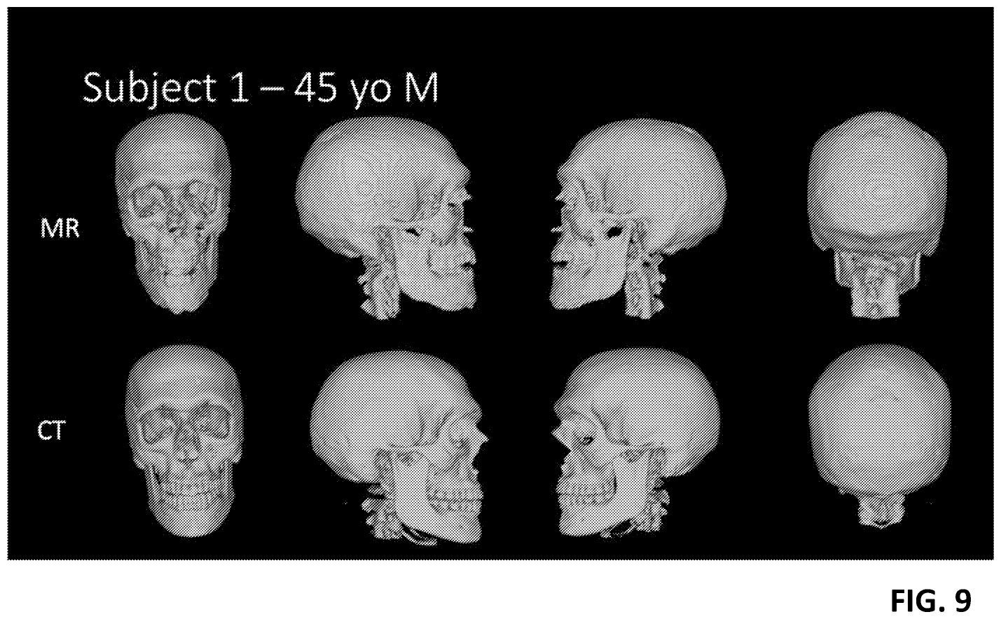

Results: Five healthy adult subjects were recruited for this study. Table 7 summarizes the demographics of the subjects. FIGS. 9-13 compare the 3D renderings of the MR and CT scans of Subjects 1-5, respectively. Tables 8-12 compare the mean craniometric measurements of Subjects 1-5, respectively.

TABLE 7

| Subject | Sex | Age | Race |
|---|---|---|---|
| 1 | Male | 45 | White |
| 2 | Female | 26 | Asian |
| 3 | Male | 27 | Black |
| 4 | Female | 27 | Black |
| 5 | Male | 35 | Asian |

FIG. 9 shows a comparison of MR and CT images of subject 1, a 45 year old male. A comparison of craniometric measurements of subject 1 are shown in Table 8.

TABLE 8

| Mean Measurement | Modality | | | |
|---|---|---|---|---|
| (cm ± SD) | MR | CT | difference | % difference |
| Cranial length | 19.1 ± 0.1 | 19.0 ± 0.1 | 0.1 | 0.7 |
| Cranial width | 14.4 ± 0.1 | 14.4 ± 0.1 | 0.0 | 0.3 |
| L orbit height | 3.3 ± 0.1 | 3.4 ± 0.1 | 0.1 | −3.0 |
| R orbit height | 3.4 ± 0.1 | 3.4 ± 0.1 | 0.0 | −0.3 |
| Piriform aperture | 3.5 ± 0.1 | 3.5 ± 0.1 | 0.0 | 0.0 |
| Inter-zygomatic arch width | 13.3 ± 0.3 | 12.8 ± 0.2 | 0.5 | 4.2 |
| Mandibular height | 2.8 ± 0.1 | 2.6 ± 0.1 | 0.2 | 9.0 |
| Maxilla width | 5.8 ± 0.1 | 6.l ± 0.1 | −0.3 | −5.1 |

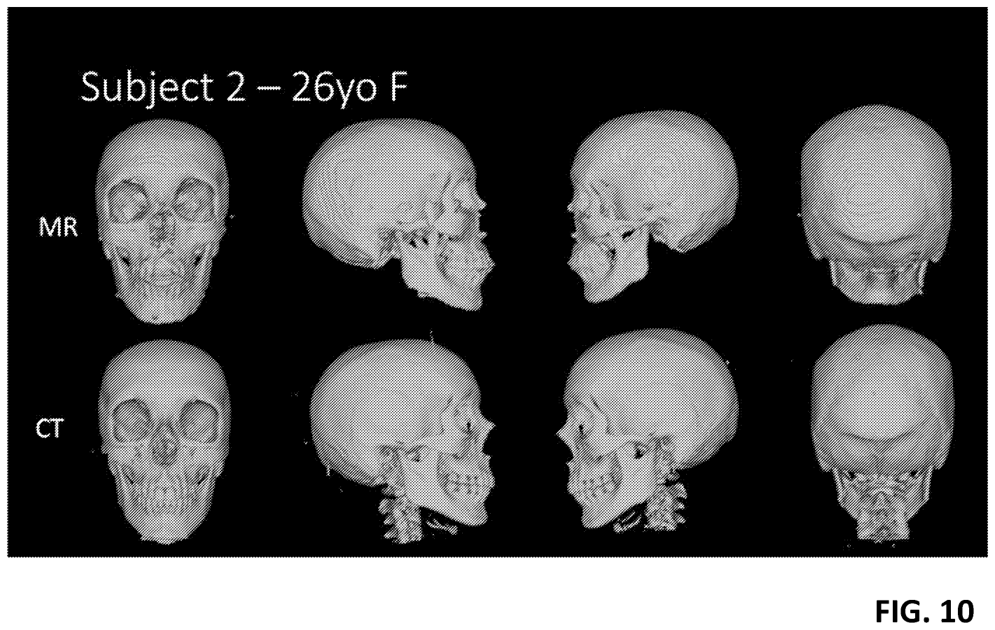

FIG. 10 shows a comparison of MR and CT images of subject 2, a 26 year old female. A comparison of craniometric measurements of subject 2 are shown in Table 9.

TABLE 9

| Mean Measurement | Modality | | | |
|---|---|---|---|---|
| (cm ± SD) | MR | CT | difference | % difference |
| Cranial length | 18.0 ± 0.1 | 18.0 ± 0.1 | 0.0 | 0.0 |
| Cranial width | 14.3 ± 0.0 | 14.2 ± 0.1 | 0.1 | 0.7 |
| L orbit height | 3.6 ± 0.1 | 3.4 ± 0.1 | 0.2 | 6.0 |
| R orbit height | 3.5 ± 0.1 | 3.5 ± 0.1 | 0.0 | 0.0 |
| Piriform aperture | 2.7 ± 0.1 | 2.7 ± 0.1 | 0.0 | 1.3 |
| Inter-zygomatic arch width | 12.5 ± 0.1 | 12.6 ± 0.1 | −0.1 | −1.0 |
| Mandibular height | 2.0 ± 0.0 | 2.2 ± 0.1 | −0.2 | −11.1 |
| Maxilla width | 5.9 ± 0.0 | 6.1 ± 0.0 | −0.2 | −3.2 |

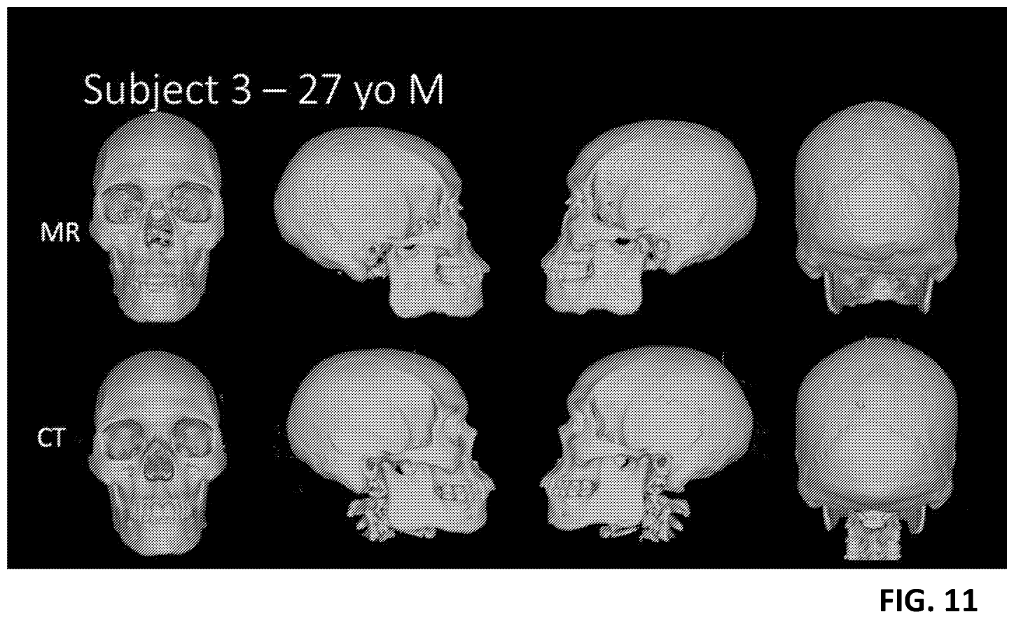

FIG. 11 shows a comparison of MR and CT images of subject 3, a 27 year old male. A comparison of craniometric measurements of subject 3 are shown in Table 10.

TABLE 10

| Mean Measurement | Modality | | | |
|---|---|---|---|---|
| (cm ± SD) | MR | CT | difference | % difference |
| Cranial length | 18.9 ± 0.1 | 19.5 ± 0.1 | −0.6 | −3.1 |
| Cranial width | 13.5 ± 0.1 | 13.4 ± 0.1 | 0.1 | 0.4 |
| L orbit height | 3.4 ± 0.1 | 3.3 ± 0.2 | 0.1 | 2.7 |
| R orbit height | 3.4 ± 0.2 | 3.5 ± 0.1 | −0.1 | −3.2 |
| Piriform aperture | 3.6 ± 0.1 | 3.1 ± 0.0 | 0.5 | 15.2 |
| Inter-zygomatic arch width | 13.7 ± 0.0 | 13.5 ± 0.1 | 0.2 | 1.3 |
| Mandibular height | 2.8 ± 0.1 | 2.7 ± 0.1 | 0.1 | 5.2 |
| Maxilla width | 7.4 ± 0.1 | 6.8 ± 0.1 | 0.6 | 9.0 |

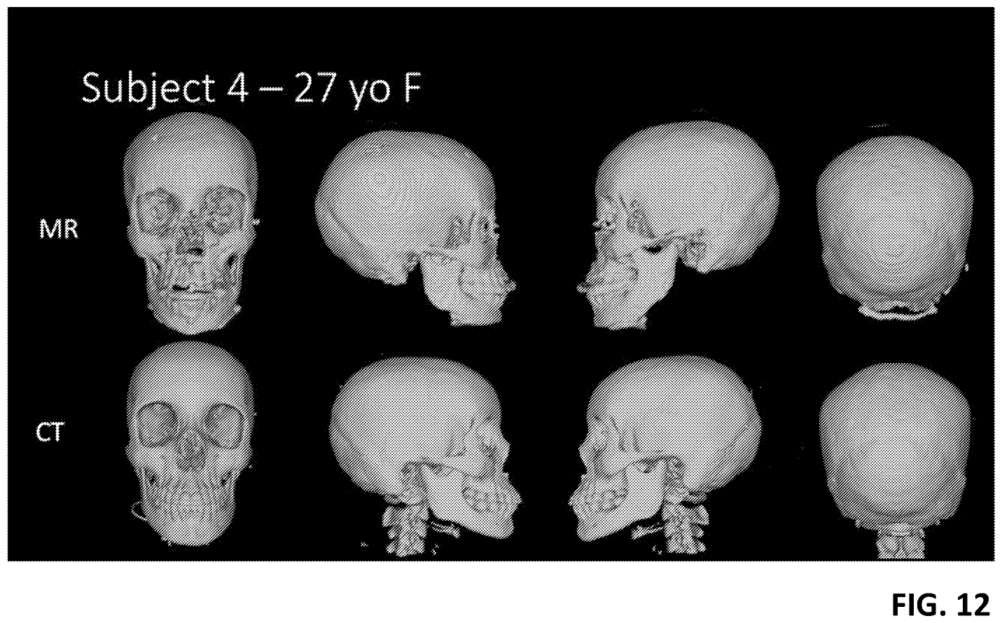

FIG. 12 shows a comparison of MR and CT images of subject 4, a 27 year old female. A comparison of craniometric measurements of subject 4 are shown in Table 11.

TABLE 11

| Mean Measurement | Modality | | | |
|---|---|---|---|---|
| (cm ± SD) | MR | CT | difference | % difference |
| Cranial length | 17.9 ± 0.1 | 18.2 ± 0.1 | −0.3 | −1.4 |
| Cranial width | 13.5 ± 0.1 | 13.3 ± 0.1 | 0.2 | 1.1 |
| L orbit height | 3.6 ± 0.1 | 3.7 ± 0.1 | −0.1 | −2.5 |
| R orbit height | 3.6 ± 0.1 | 3.7 ± 0.1 | −0.1 | −2.5 |
| Piriform aperture | 3.1 ± 0.1 | 3.1 ± 0.1 | 0.0 | −1.2 |
| Inter-zygomatic arch width | 11.8 ± 0.1 | 11.8 ± 0.1 | 0.0 | 0.1 |
| Mandibular height | 2.3 ± 0.1 | 2.2 ± 0.1 | 0.1 | 4.3 |
| Maxilla width | 5.9 ± 0.0 | 5.6 ± 0.1 | 0.3 | 5.3 |

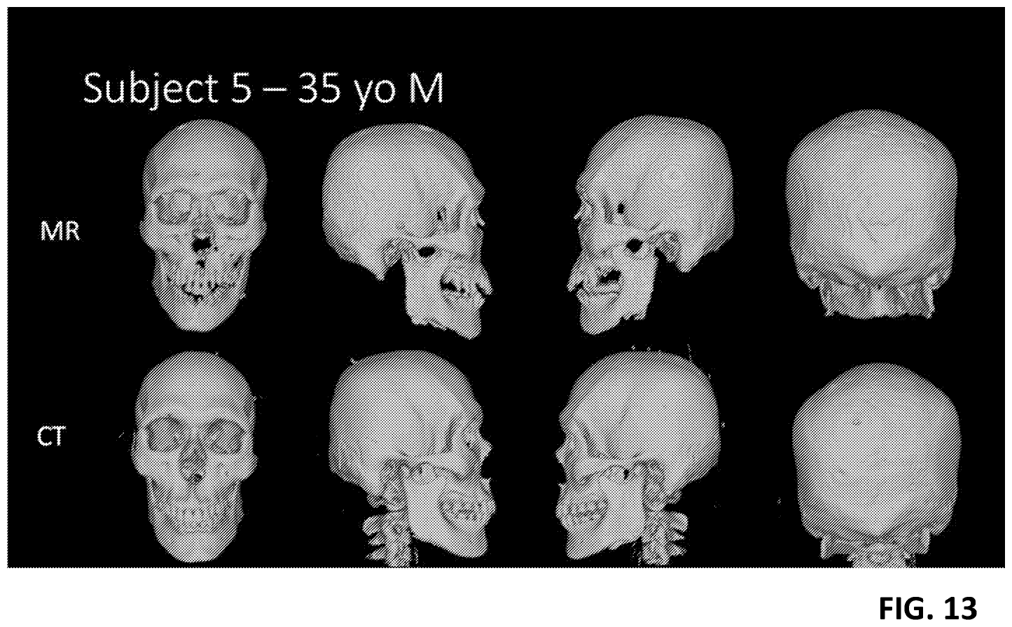

FIG. 13 shows a comparison of MR and CT images of subject 5, a 35 year old male. A comparison of craniometric measurements of subject 5 are shown in Table 12.

TABLE 12

| Mean Measurement | Modality | | | |
|---|---|---|---|---|
| (cm ± SD) | MR | CT | difference | % difference |
| Cranial length | 18.4 ± 0.1 | 18.7 ± 0.1 | −0.3 | −1.6 |
| Cranial width | 16.0 ± 0.1 | 15.8 ± 0.1 | 0.2 | 1.3 |
| L orbit height | 3.8 ± 0.1 | 3.4 ± 0.1 | 0.4 | 11.1 |
| R orbit aperture height | 3.5 ± 0.1 | 3.5 ± 0.1 | 0.0 | 0.0 |
| Piriform aperture | 3.7 ± 0.1 | 3.7 ± 0.1 | 0.0 | 0.0 |
| Inter-zygomatic arch width | 16.0 ± 0.1 | 15.2 ± 0.2 | 0.8 | 5.1 |
| Mandibular height | 3.0 ± 0.1 | 3.2 ± 0.1 | −0.2 | −6.5 |
| Maxilla width | 8.1 ± 0.1 | 8.1 ± 0.1 | 0.0 | 0.0 |

Table 13 summarizes the mean percent differences and Lin's Concordance correlation coefficients for the five subjects.

TABLE 13

| | | Lin's | |
|---|---|---|---|
| | | Concordance | |
| | Mean percent difference | Correlation | |
| Subject | (% ± SD) | Coefficient | 95% CI |
| 1 | 0.7 ± 4.3 | 0.999 | 0.998-1.000 |
| 2 | −0.9 ± 4.9 | 1.000 | 0.999-1.000 |
| 3 | 3.4 ± 6.2 | 0.998 | 0.995-1.001 |
| 4 | 0.4 ± 3.0 | 1.000 | 0.999-1.000 |
| 5 | 1.2 ± 5.1 | 0.998 | 0.996-1.001 |

Discussion: The proposed MR sequence produced bone-specified images of healthy adult subject skulls, with sufficiently high resolution for 3D rendering. Eight anatomic distance measurements obtained from MR and CT images yielded percent differences ranging from −0.9% to 3.4%, and concordance coefficients ranging from 0.998 to 1.000, corresponding to a substantial strength of agreement³³. These results suggest that the method has good reliability for adult skull imaging when compared to CT. Notably, the method was reliable for imaging of human adult subject skulls despite the presence of significantly more soft tissue than the pre-stripped human cadaver skull described herein.

Lambdoid sutures can be observed in MR-based 3D renderings of all five skulls, most prominently in Subject 4 (e.g., as shown in FIG. 12, column 4). However for all subjects, the sutures are more defined in the CT-based 3D renderings.

Comparison of CT and Bone-Selective MRI for 3D Rendering of Pediatric Patient Skull.

The objectives of this study were to 1) produce 3D skull renderings of pediatric craniofacial patients, using a novel bone-selective MRI technique 2) compare visualization of cranial sutures and the biometric accuracy of anatomical measurements obtained from CT-based and MRI-based 3D renderings.

Methods are described as follows.

Imaging technique: The bone-selective MR pulse sequence was previously described herein.

Data acquisition/processing: MR imaging parameters were as previously described herein. No contrast or non-clinically indicated sedation was used for any subject.

All subjects were imaged in the same MRI scanner (Siemens Prisma, Erlangen, Germany) with a 20-channel head coil.

Each subject additionally underwent a clinical head CT scan, as a gold standard comparison to the bone-selective MR scan. The 0.75 mm slice thickness is the CHOP clinical standard for 3D Head CT scans used for craniofacial imaging and surgical planning. A single scanner (GE Medical Systems, Milwaukee, Ill.) was used for all scans.

3D rendering of MR and CT scans, as well as comparison of craniometric measurements, were performed as described herein.

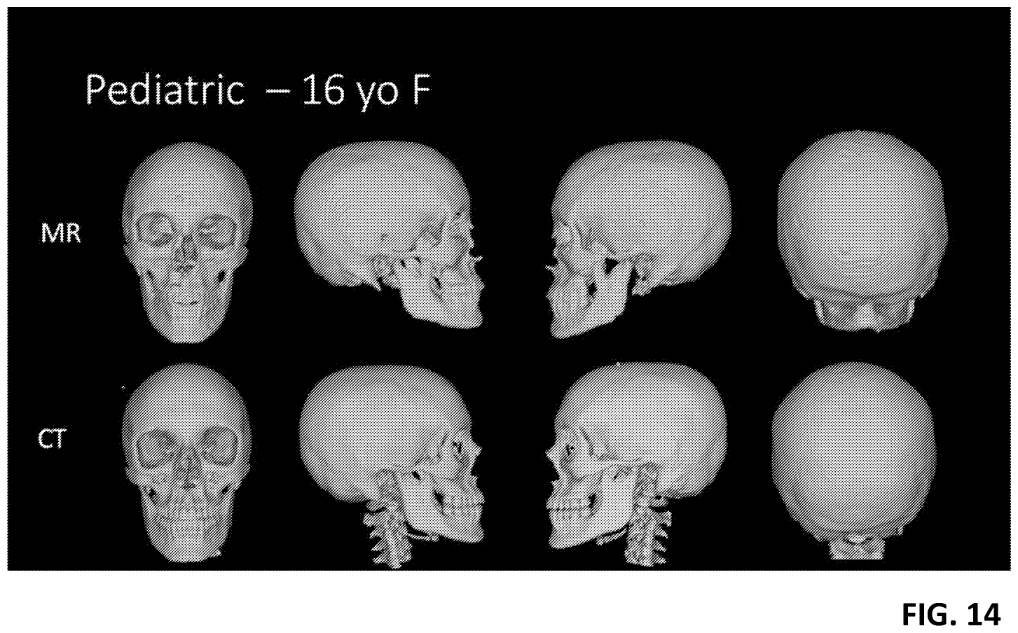

FIG. 14 shows a comparison of MR and CT images of a pediatric subject 16 years of age. A comparison of craniometric measurements of the pediatric subject are shown in Table 14.

TABLE 14

| | Modality | | | |
|---|---|---|---|---|
| Mean Measurement (cm ± SD) | MR | CT | difference | % difference |
| Cranial length | 18.1 ± 0.1 | 18.4 ± 0.1 | −0.3 | −1.6 |
| Cranial width | 14.8 ± 0.1 | 14.6 ± 0.1 | 0.2 | 1.4 |
| L orbit height | 3.4 ± 0.2 | 3.5 ± 0.1 | −0.1 | −2.0 |
| R orbit height | 3.3 ± 0.2 | 3.4 ± 0.1 | 0.0 | −3.0 |
| Piriform aperture | 3.5 ± 0.1 | 3.2 ± 0.2 | 0.3 | 9.0 |
| Inter-zygomatic arch width | 13.0 ± 0.2 | 12.8 ± 0.3 | 0.2 | 1.6 |
| Mandibular height | 2.6 ± 0.1 | 2.6 ± 0.1 | 0.0 | 0.0 |
| Maxilla width | 6.6 ± 0.0 | 6.5 ± 0.1 | 0.1 | 1.5 |

### Mean MR Vs CT Percent Difference: 0.7%+/−3.8

Table 15 shows comparison of MR and CT using Lin's concordance correlation coefficient.

TABLE 15

| | Lin's | |
|---|---|---|
| | Concordance | |
| | Correlation | |
| Comparison | Coefficient | 95% CI |
| MR vs CT | 0.999 | 0.999-1.000 |

Discussion: The results suggest that most facial structures were rendered appropriately, as compared to CT-based 3D renderings. The concordance correlation coefficient of 0.999 was similar to those of the adult healthy subjects.

Summary: DURANDE UTE in combination with the bone-selective image reconstruction enables high-resolution (˜1.1 mm) skull imaging of the whole head in six minutes. The dual-RF based UTE bone imaging method enhances differentiation of cortical bone from long T₂ species (such as soft tissue). The resolution and differentiation of the cortical bone enabled semi-automatic segmentation of MR images and subsequent 3D rendering of the skull. Craniometric measurement comparisons suggested high concordance (concordance coefficient >0.990) of the bone-selective MR method in comparison to the current clinical standard of thin-slice 3D head CT.

30) The data show that the disclosed bone-specific MRI pulse sequence and reconstruction algorithm, along with the segmentation and image rendering method, provides images of the younger pediatric skull comparable to those obtainable by CT. Results in the cadaver skull study suggest excellent agreement between the new solid-state MRI technique and cadaver craniometric measurements, as well as between MRI and CT. Similarly high agreement between MRI and CT modalities were seen in scans of five healthy adult subjects and one adolescent patient.

In addition to accurate measurements and modeling of the skull at time of surgery, the ability to predict future changes in shape based on growth patterns, is useful for surgical planning. Furthermore, a database of normal skull morphology across multiple age groups can be used to create a statistical model for normal skull bone growth, which could be broadly applicable to both clinical and translational research projects. For example, the model can provide a normal comparison with which to assess post-operative results of craniofacial repairs.

### REFERENCES FOR THIS SECTION

1. Fearon J, Singh D, Beals S, Yu J. The Diagnosis and Treatment of {Single-Sutural} Synostoses: Are Computed Tomographic Scans Necessary? Plast Reconstr Surg. 2007; 120(5):1327. doi:10.1097/01.prs.0000279477.56044.55.
2. Krille L, Dreger S, Schindel R, et al. Risk of cancer incidence before the age of 15-years after exposure to ionising radiation from computed tomography: results from a German cohort study. Radiat Env Bioph. 2015; 54(1):1-12. doi:10.1007/s00411-014-0580-3.
3. Rebecca S-B, Lipson J, Marcus R, et al. Radiation Dose Associated With Common Computed Tomography Examinations and the Associated Lifetime Attributable Risk of Cancer. Arch Intern Med. 2009; 169(22):2078-2086. doi:10.1001/archinternmed.2009.427.
4. Mathews J D, Forsythe A V, Brady Z, et al. Cancer risk in 680 000 people exposed to computed tomography scans in childhood or adolescence: data linkage study of 11 million Australians. Bmj. 2013; 346(may21 1):f2360. doi:10.1136/bmj.f2360.
5. Miglioretti D L, Johnson E, Williams A, et al. The Use of Computed Tomography in Pediatrics and the Associated Radiation Exposure and Estimated Cancer Risk. Jama Pediatr. 2013; 167(8):700-707. doi:10.1001/jamapediatrics.2013.311.
6. Kuhns L R, Oliver W J, Christodoulou E, Goodsitt M M. The Predicted Increased Cancer Risk Associated With a Single Computed Tomography Examination for Calculus Detection in Pediatric Patients Compared With the Natural Cancer Incidence. Pediatr Emerg Care. 2011; 27(4):345. doi:10.1097/PEC.0b013e3182132016.
7. Kmietowicz Z. Computed tomography in childhood and adolescence is associated with small increased risk of cancer. Bmj. 2013; 346(may22 16):f3348. doi:10.1136/bmj.f3348.
8. Fazel R, Krumholz H M, Wang Y, et al. Exposure to {Low-Dose} Ionizing Radiation from Medical Imaging Procedures. New Engl J Med. 2009; 361(9):849-857. doi:10.1056/NEJMoa0901249.
9. de González A, Mahesh M, Kim K-P, et al. Projected Cancer Risks From Computed Tomographic Scans Performed in the United States in 2007. Arch Intern Med. 2009; 169(22):2071-2077. doi:10.1001/archintemmed.2009.440.
10. Redberg R F. Cancer Risks and Radiation Exposure From Computed Tomographic Scans: How Can We Be Sure That the Benefits Outweigh the Risks? Arch Intern Med. 2009; 169(22):2049-2050. doi:10.1001/archintemmed.2009.453.
11. Pearce M S, Salotti J A, Little M P, et al. Radiation exposure from C T scans in childhood and subsequent risk of leukaemia and brain tumours: A retrospective cohort study. Lancet. 2012; 380(9840):499-505. doi:10.1016/S0140-6736(12)60815-0.
12. Parthasarathy J. {3D} modeling, custom implants and its future perspectives in craniofacial surgery. Ann Maxillofac Surg. 2014.
13. Eley K A, Sheerin F, Taylor N, R W-S S, Golding S J. Identification of normal cranial sutures in infants on routine magnetic resonance imaging. 2013; 24(1):317-320.
14. Eley K A, Mcintyre A G, Watt-Smith S R, Golding S J. “Black bone” MRI: A partial flip angle technique for radiation reduction in craniofacial imaging. Br J Radiol. 2012; 85(1011):272-278. doi:10.1259/bjr/95110289.
15. Eley K A, Watt-Smith S R, Sheerin F, Golding S J. “Black Bone” MRI: a potential alternative to C T with three-dimensional reconstruction of the craniofacial skeleton in the diagnosis of craniosynostosis. Eur Radiol. 2014:2417-2426. doi:10.1007/s00330-014-3286-7.
16. Bergin C J, Pauly J M, Macovski A. Lung parenchyma: projection reconstruction {MR} imaging. Radiology. 1991; 179(3):777-781. doi:10.1148/radiology.179.3.2027991.
17. Robson M D, Gatehouse P D, Bydder M, Bydder G M. Magnetic Resonance: An Introduction to Ultrashort {TE} {(UTE)} Imaging. J Comput Assist Tomo. 2003; 27(6):825. doi:10.1097/00004728-200311000-00001.
18. Madio D, Lowe I. Ultra-fast imaging using low flip angles and fids. Magn Reson Med. 1995; 34(4):525-529. doi:10.1002/mrm.1910340407.
19. Weiger M, Pruessmann K, Hennel F. {MRI} with zero echo time: Hard versus sweep pulse excitation. Magn Reson Med. 2011; 66(2):379-389. doi:10.1002/mrm.22799.
20. Techawiboonwong A, Song H, Wehrli F. In vivo {MRI} of submillisecond T2 species with two-dimensional and three-dimensional radial sequences and applications to the measurement of cortical bone water. Nmr Biomed. 2008; 21(1):59-70. doi:10.1002/nbm.1179.
21. Du J, Carl M, Bydder M, Takahashi A, Chung C, Bydder G. Qualitative and quantitative ultrashort echo time {(UTE)} imaging of cortical bone. J Magn Reson. 2010; 207(2):304-311. doi:10.1016/j.jmr.2010.09.013.
22. Wu Y, Hrovat M I, Ackerman J L, et al. Bone matrix imaged in vivo by water- and fat-suppressed proton projection {MRI} {(WASPI)} of animal and human subjects. J Magn Reson Imaging. 2010; 31(4):954-963. doi:10.1002/jmri.22130.
23. Wu Y, Chesler D, Glimcher M, et al. Multinuclear solid-state three-dimensional {MRI} of bone and synthetic calcium phosphates. Proc Natl Acad Sci. 1999; 96(4):1574-1578. doi:10.1073/pnas.96.4.1574.
24. Seifert A, Li C, Rajapakse C, et al. Bone mineral {31P} and matrix-bound water densities measured by solid-state {31P} and {1H} {MRI}. Nmr Biomed. 2014; 27(7):739-748. doi:10.1002/nbm.3107.
25. Wiesinger F, Sacolick L I, Menini A, et al. Zero TEMR bone imaging in the head. Magn Reson Med. 2016; 75(1):107-114. doi:10.1002/mrm.25545.
26. Du J, Diaz E, Carl M, Bae W, Chung C, Bydder G. Ultrashort echo time imaging with bicomponent analysis. Magn Reson Med. 2012; 67(3):645-649. doi:10.1002/mrm.23047.
27. Li C, Magland J F, Rad H, Song H, Wehrli F W. Comparison of optimized soft-tissue suppression schemes for ultrashort echo time {MRI}. Magn Reson Med. 2012; 68(3):680-689. doi:10.1002/mrm.23267.
28. Rahmer J, Blume U, Bomert P. Selective {3D} ultrashort {TE} imaging: comparison of “dual-echo” acquisition and magnetization preparation for improving {short-T2}contrast. Magn Reson Mater Phys Biol Med. 2007; 20(2):83. doi:10.1007/s10334-007-0070-6.
29. Johnson E M, Vyas U, Ghanouni P, Pauly K, Pauly J M. Improved cortical bone specificity in {UTE} {MR} Imaging. Magn Reson Med. 2017; 77(2):684-695. doi:10.1002/mrm.26160.
30. Lee H, Zhao X, Song H K, Zhang R, Bartlett S P, Wehrli F W. Rapid dual-R F, dual-echo, 3D ultrashort echo time craniofacial imaging: A feasibility study. Magn Reson Med. 2019. doi:10.1002/mrm.27625.
31. Grodzki D M, Jakob P M, Heismann B. Ultrashort echo time imaging using pointwise encoding time reduction with radial acquisition {(PETRA)}. Magn Reson Med. 2012; 67(2):510-518. doi:10.1002/mrm.23017.
32. Yushkevich P A, Gao Y, Gerig G. {ITK-SNAP:} An interactive tool for semi-automatic segmentation of multi-modality biomedical images. Conf Proc {IEEE} Eng Med Biol Soc. 2016; 2016:3342-3345. doi:10.1109/EMBC.2016.7591443.
33. Lin L I, McBride G, Bland J M, Altman D G. A proposal for strength-of-agreement criteria for Lin's Concordance Correlation Coefficient. NIWA Client Rep. 2005; 45(1):307-310. doi:10.2307/2532051.
34. Margulies S S, Thibault K L. Infant Skull and Suture Properties: Measurements and Implications for Mechanisms of Pediatric Brain Injury. J Biomech Eng. 2000; 122(4):364-371. doi:10.1115/1.1287160.
35. Kriewall T J, K M G, Tsai A. Bending properties and ash content of fetal cranial bone. J Biomech. 1981; 14(2):73-79. doi:10.1016/0021-9290(81)90166-4.
36. Wang H, Suh J, Das S, Pluta J, Craige C, Yushkevich P. {Multi-Atlas}Segmentation with Joint Label Fusion. Ieee T Pattern Anal. 2013; 35(3):611-623. doi:10.1109/TPAMI.2012.143.
37. Iglesias J, Sabuncu M. Multi-atlas segmentation of biomedical images: A survey. Med Image Anal. 2015; 24(1):205-219. doi:10.1016/j.media.2015.06.012.
38. Chan R W, Ramsay E A, Cunningham C H, Plewes D B. Temporal stability of adaptive 3D radial MRI using multidimensional golden means. Magn Reson Med. 2009. doi:10.1002/mrm.21837.
39. Anderson A G, Velikina J, Block W, Wieben O, Samsonov A. Adaptive retrospective correction of motion artifacts in cranial MRI with multicoil three-dimensional radial acquisitions. Magn Reson Med. 2013. doi:10.1002/mrm.24348.

### Motion Correction

Solid-state MRI via 3D ultrashort echo-time (UTE)¹ or zero TE² methods, capable of detecting signals from protons with very short T₂ relaxation times, has potential for bone-selective imaging³⁻⁵, for instance as a radiation-free alternative to computed tomography for the pre- and post-surgical evaluation of children with craniofacial abnormalities. However, relatively long scan times make the technique vulnerable to artifacts from involuntary subject movements, thereby impairing image quality. Here, we developed a self-navigated, rapid 3D UTE technique by combining a retrospective motion detection/correction approach⁶ with sparsity-constrained image reconstruction. In vivo studies were performed to investigate the feasibility of the proposed method in achieving rapid, motion-resistant whole-skull imaging.

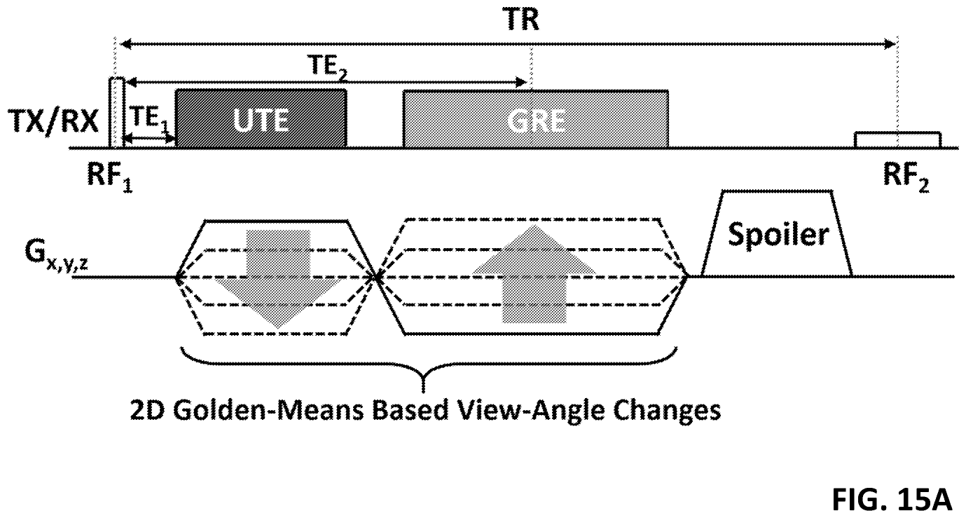

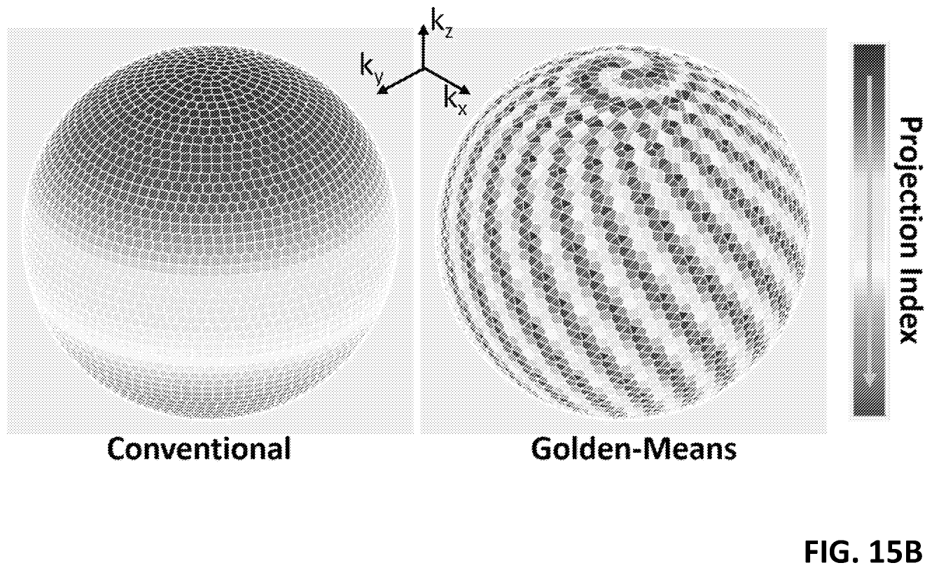

Methods: FIG. 15A shows a diagram of the dual-RF and dual-echo 3D UTE pulse sequence, in which RF1 (short 40 μs) and RF² (long˜520 μs) are alternately played out while two signals, such as UTE and gradient recalled echo (GRE), are produced with the gradient polarity reversed. FIG. 15B shows comparison of view-orders in distributing projections (number: 4096) in 3D k-space between conventional (left) and the proposed (right) methods. Note that with the 2D golden means based view ordering strategy, any subset of consecutive views is distributed near-evenly in 3D k-space.

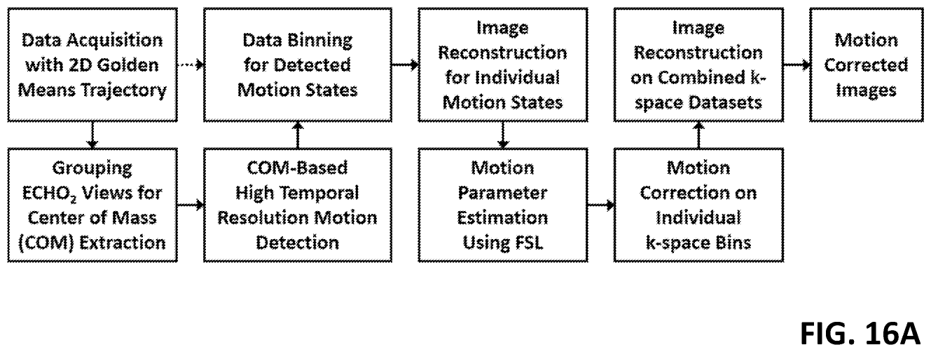

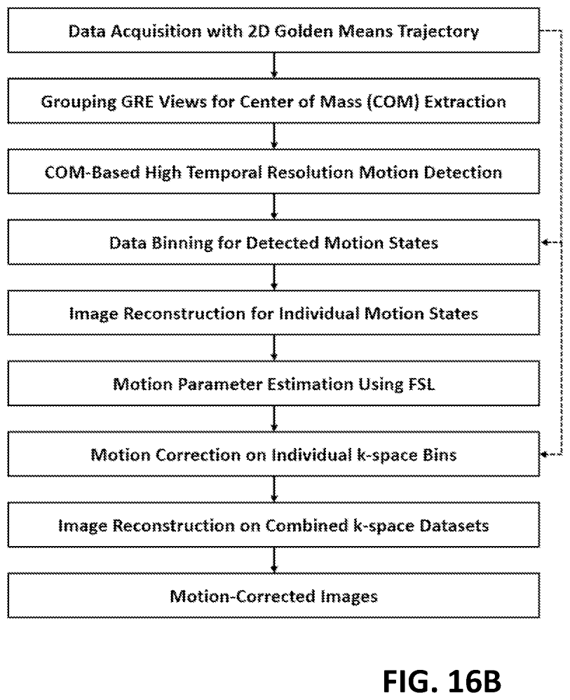

Motion detection and correction: FIG. 15A shows a diagram of the proposed pulse sequence. While retaining the dual-RF/dual-echo configuration⁴ and the view-sharing scheme⁷ for achieving high bone specificity with enhanced imaging efficiency, the method employs a multi-dimensional golden-means (GM) based k-space trajectory⁸ for retrospective motion detection and correction⁶. Specifically, GRE signals acquired as full projections (as shown in FIG. 15A) are employed to derive the center of mass (COM) using the relationship⁹

$${γ}_{C O M} ( θ ) = \frac{\int r ( r , θ ) dr}{\int ( r , θ ) dr}$$

where γ_{COM}(θ) is the projection of COM onto a radial line with the angle θ, and [symbol] the Radon transform of the object. The time-course of COM during data collection is then analyzed or adaptive determination of motion states, within each of which sampling views are distributed near-evenly in 3D k-space thereby allowing reconstruction of low-resolution images representative of a particular motion state. Subsequently, rigid-motion parameters are extracted for individual motion states via FSL¹⁰, leading to correction of acquired k-space datasets. The final, high-resolution motion-corrected images are obtained using the reconstruction method described below. The above procedures are summarized in FIGS. 16A-B. FIG. 16A is a flowchart shown an example method for motion correction of an image. FIG. 16B is a flowchart showing another example method for motion correction of an image.

Bone-selective image reconstruction: Given the sparse bone signals in the difference between short and long TE images, bone-specific imaging is further accelerated with fewer radial lines by exploiting such sparsity during image reconstruction^{11, 12}. The following sparse signal recovery problem can then be formulated:

$${min}_{{I}_{1} , {I}_{2}} \frac{1}{2} {\sum }_{j = 1}^{{N}_{c}} \{ {‖ {k}_{1 , j} - {F}_{N U} ( {S}_{j} {I}_{1} ) ‖}_{2}^{2} + {‖ {k}_{2 , j} - {F}_{N U} ( {S}_{j} {J}_{2} ) ‖}_{2}^{2} \} + λ {‖ {I}_{1} - {I}_{2} {e}^{- i ϕ} ‖}_{1} \qquad ( 3 )$$

where k₁/k₂ are the motion-corrected and view-shared k-space data at TE₁/TE₂, and I₁/I₂ are the corresponding complex images, [symbol] _{NU} is the non-uniform fast FT (NUFFT), Sⱼ is the receive sensitivity for the j-th coil, N_{c} and λ are the number of receive coil elements and regularization parameter, respectively, and φ is the phase accrual during ΔTE. The phase correction with φ in the subtraction is important, as otherwise residual sparsity may be disrupted. Both S and (are spatially smooth and thus can be estimated using over-sampled, central k-space data. The solutions (I₁, I₂) are found with an alternating minimization approach that splits Eq. 3 into two sub-problems with respect to I₁ and I₂. The two solutions are iteratively updated until convergence is reached.

In vivo studies: Two subjects were scanned at 3 T (Siemens Prisma) using the following parameters: TR/TE₁/TE₂=5.0/0.06/1.84 ms, RF₁/RF₂ durations=40/520 μs, flip-angle=120 (identical for RF₁ and RF₂), matrix size=2563, field-of-view=2563 mm³, and readout bandwidth=±125 kHz. A 20-channel head/neck coil was used for signal reception. Both subjects were instructed to move the head three to four times during each scan. To test the sequence's self-navigation effectiveness, data were acquired in the first subject using a relatively large number of views (50,000 for each echo; scan time=8.4 min). Following the motion detection/correction steps, images for UTE (I₁) from RF₁ and GRE (12) from RF2 were reconstructed using inverse NUFFT. Bone-specific images (I_{Bone}) were then obtained as I_{Bone} (I₁−I₂)/(I₁+I₂). In the second subject, data were prospectively undersampled using 12,500 views (scan time=2.1 min). Motion-corrected and view-shared k-space datasets were then processed to reconstruct images using Eq. 3.

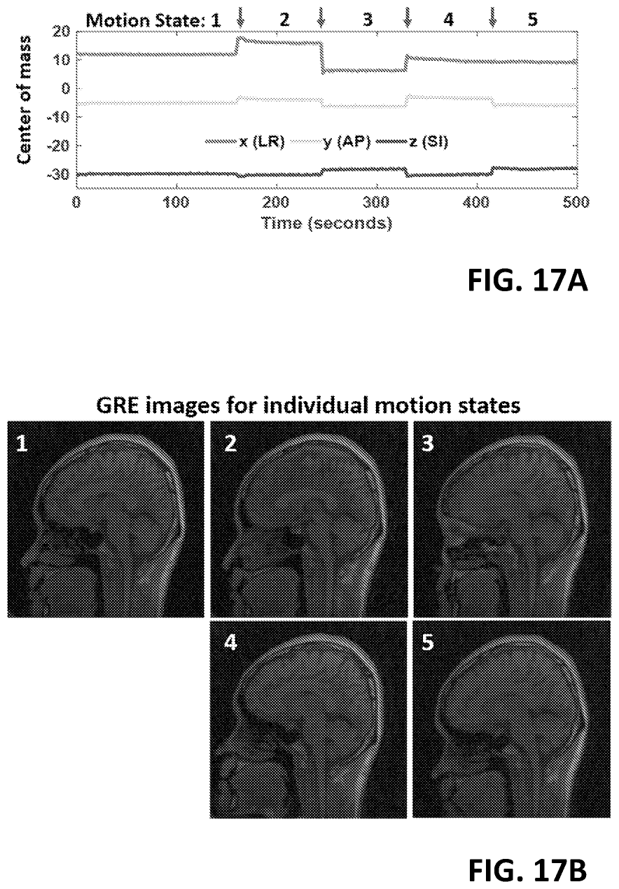

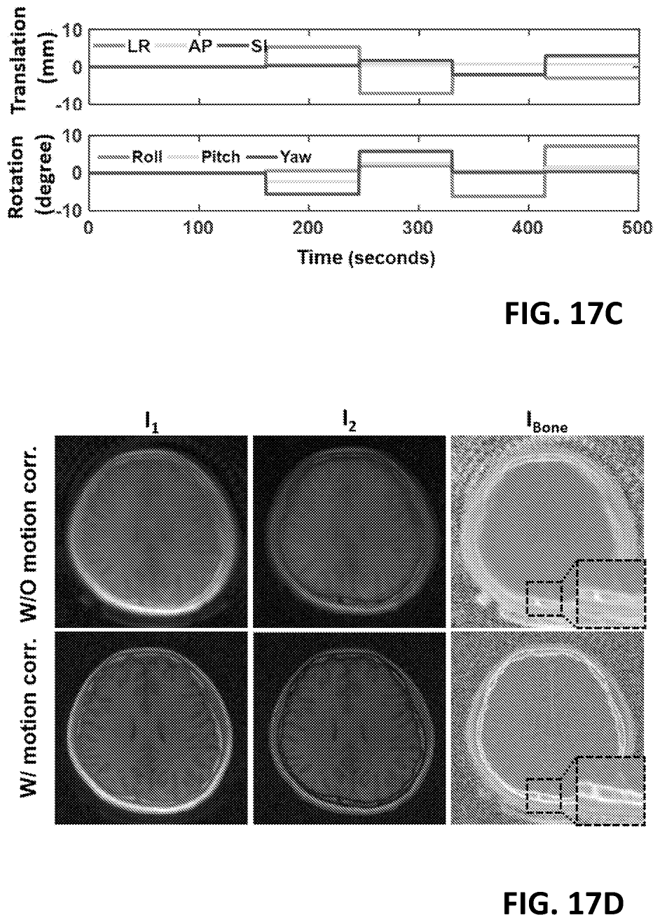

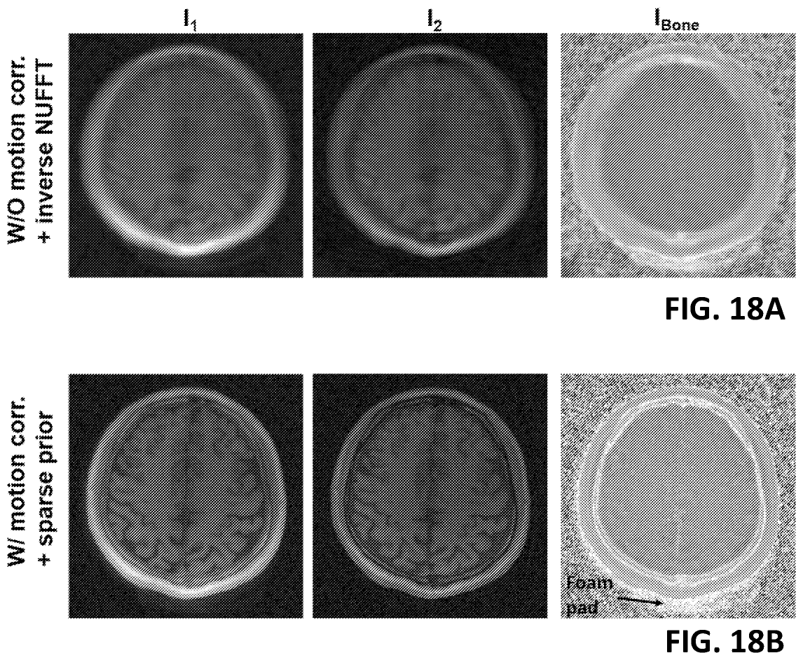

Results: FIGS. 17A-D displays results from each processing step in FIG. 16A. The time-course of COM accurately reflects four occurrences of the subject's head motion (FIG. 17A), leading to five sets of GRE image corresponding to each motion state (FIG. 17B). Correction of k-space datasets using the estimated rigid-motion parameters (FIG. 17C) yields clear depiction of inner and outer table of the cranium in I_{Bone} after removal of motion-induced image blurring in both UTE and GRE images (FIG. 17D). FIGS. 18A-B compare two sets of images from the second subject; one reconstructed directly using inverse NUFFT (FIG. 18A) and one with motion correction followed by sparse reconstruction (FIG. 18B). Image blurring and artifacts due to subject motion and data subsampling are effectively eliminated using the proposed method.

Conclusions: Results suggest the proposed method to be robust to head movement during scanning. Upon further optimization, the method should find applications for bone-selective head imaging as a radiation-free alternative to computed tomography in children indicated for craniofacial surgery.

### REFERENCES FOR THIS SECTION

1. Robson M D, Gatehouse P D, Bydder M, Bydder G M. Magnetic resonance: An introduction to ultrashort T E (UTE) imaging. J Comput Assist Tomogr 2003; 27:825-846.
2. Weiger M, Pruessmann K P, Hennel F. MRI with zero echo time: hard versus sweep pulse excitation. Magn Reson Med 2011; 66(2):379-389.
3. Li C, Magland J F, Zhao X, Seifert A C, Wehrli F W. Selective in vivo bone imaging with long-T suppressed PETRA MRI. Magn Reson Med 2016; 77(3):989-997.
4. Johnson E M, Vyas U, Ghanouni P, Pauly K B, Pauly J M. Improved cortical bone specificity in UTE M R imaging. Magn Reson Med 2017; 77:684-695.
5. Wiesinger F, Sacolick L I, Menini A, Kaushik S S, Ahn S, Veit-Haibach P, Delso G, Shanbhag D D. Zero TEMR bone imaging in the head. Magn Reson Med 2016; 75(1):107-114.
6. Anderson III A G, Velikina J, Block W, Wieben O, Samsonov A. Adaptive retrospective correction of motion artifacts in cranial MRI with multicoil three-dimensional radial acquisitions. Magn Reson Med 2013; 69(4):1094-1103.
7. Lee H, Zhao X, Song H K, Zhang R, Bartlett S P, Wehrli F W. Solid-state MRI as a noninvasive alternative to computed tomography for craniofacial imaging. Joint Annual Meeting ISMRM-ESMRMB 2018; 332.
8. Chan R W, Ramsay E A, Cunningham C H, Plewes D B. Temporal stability of adaptive 3D radial MRI using multidimensional golden means. Magn Reson Med 2009; 61(2):354-363.
9. Larson A C, White R D, Laub G, McVeigh E R, Li D, Simonetti O P. Self-gated cardiac cine MRI. Magn Reson Med 2004; 51(1):93-102.
10. M. Jenkinson and S. M. Smith. A global optimisation method for robust affine registration of brain images. Med Image Anal 2001; 5(2):143-156.
11. Lustig M, Donoho D, Pauly J M. Sparse MRI: The application of compressed sensing for rapid M R imaging. Magn Reson Med 2007; 58(6):1182-1195.
12. Nam S, Akcakaya M, Basha T, Stehning C, Manning W J, Tarokh V, Nezafat R. Compressed sensing reconstruction for whole-heart imaging with 3D radial trajectories: a graphics processing unit implementation. Magn Reson Med 2013; 69(1):91-102.

### Additional Information

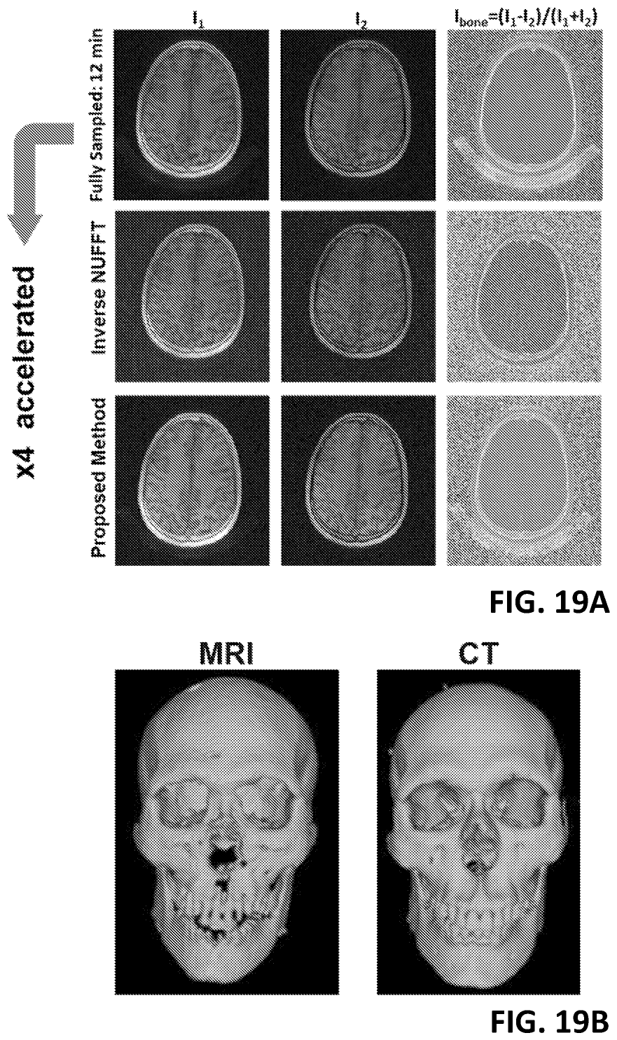

FIG. 19A shows a comparison of imaging techniques. FIG. 19B shows models reconstructed using imaging techniques. The disclosed method describes a solid-state MRI method as a non-invasive alternative to CT for skull imaging. The disclosed MRI method is based on dual-RF and dual-echo 3D UTE imaging. Also demonstrated is a feasibility of speeding up this imaging technique by exploiting view-sharing and bone-sparsity in the difference image. Based on these bone-specified images, generate this volumetric craniofacial model that is pretty comparable to CT based renderings.

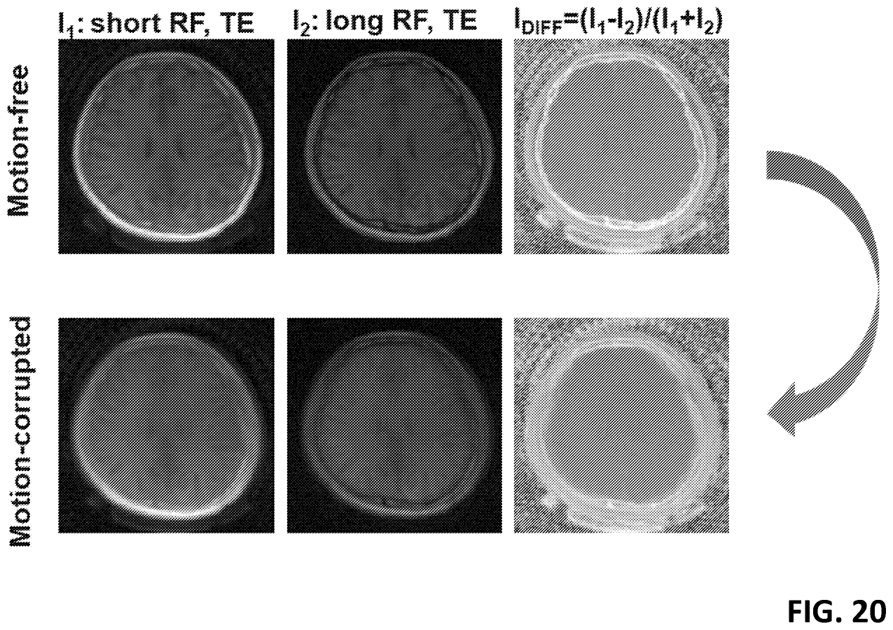

FIG. 20 shows image distortion due to motion. Even with the accelerated imaging, a subject's motion can occur at any time of sequence running, leading to image blurring and distortions. Particularly, a small amount of motion, which might be acceptable for brain structural imaging, can be a very serious problem in identifying bone-voxels, because the inner and outer tables of the skull bone are very thin.

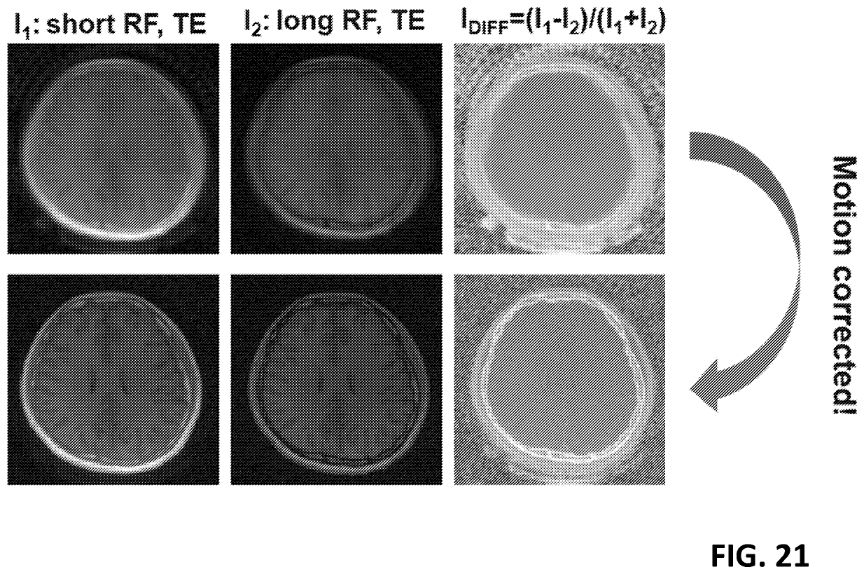

FIG. 21 shows image correction.

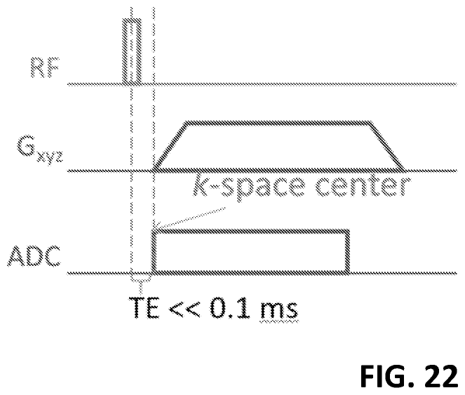

FIG. 22 shows sampling of signals. Skull imaging: motivation & solid-state MRI. Craniofacial abnormalities in newborns: 2.7%. Computed tomography (CT): excellent visualization of cortical bone. CT is the gold standard for evaluation and diagnosis of craniofacial pathologies. Ct has potentially adverse effects (e.g. risk of cancer) from repeated ionizing radiation. Solid-state MRI: UTE: ramp sampling of FID signals (FIG. 22), ZTE: gradient turned on before RF, most commonly, radial k-space with half projections, TE TX/RX switching time (<<0.1 ms)

Approaches to enhance bone contrast. Issue in specifying bone structures: High signals from soft tissues→ambiguity in bone detection.

Approaches to enhancing bone conspicuity. Post-processing: Bias field correction followed by histogram based bone voxel detection; Pre-suppression of soft-tissues: Inversion-recovery based tissue signal nulling; Post-suppression of soft-tissues: Dual-RF and dual-echo acquisition and subtraction, exploiting the signal sensitivity of short T2* species to both RF pulse length and TE

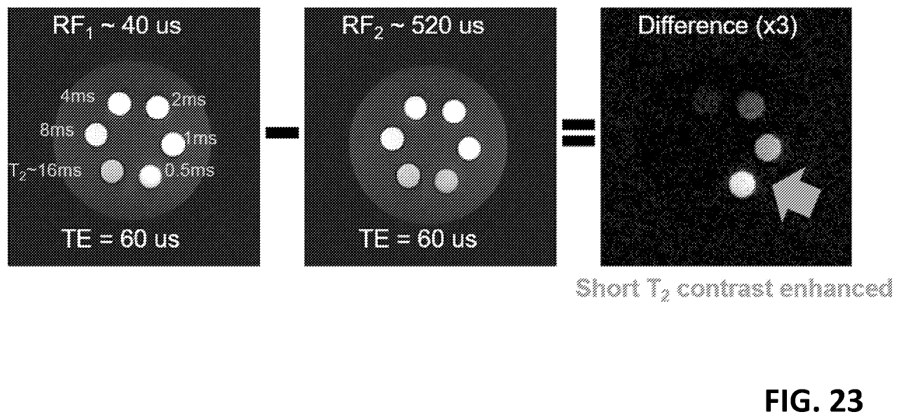

FIG. 23 shows Dual-RF UTE. Dual-RF UTE. Issue: scan time doubled due to interleaving two RF pulses. Solution: view-sharing between echoes from the two RF pulses.

The disclosed techniques can comprise one or more of a self-navigated, 3D dual-RF & dual-echo (DURANDE) UTE pulse sequence; retrospective motion correction for motion-insensitive skull bone MRI; an accelerated the sequence and reconstruct images with a prior: bone-sparsity in echo-difference.

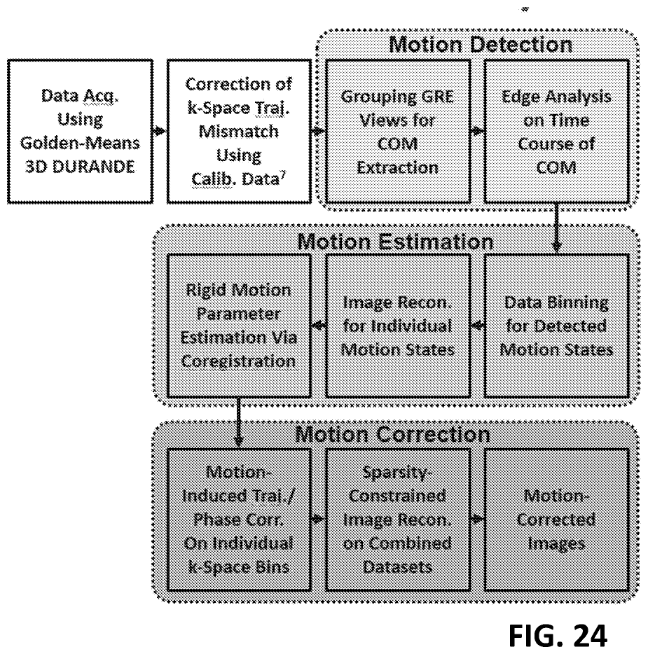

FIG. 24 shows exemplary motion correction steps.

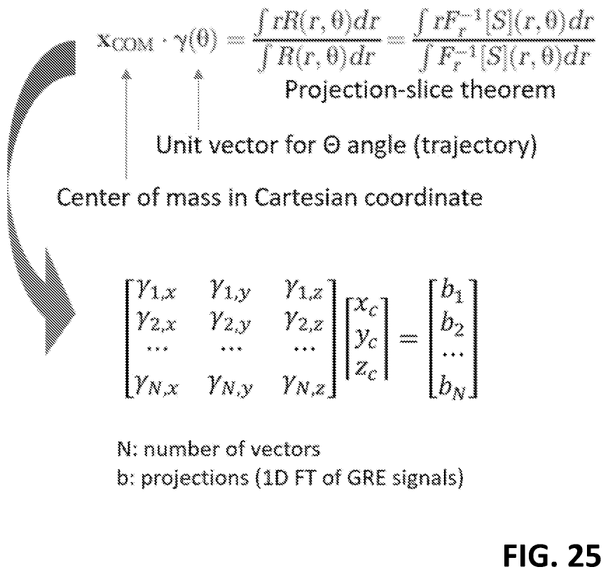

FIG. 25 shows exemplary motion detection and COM derivation.

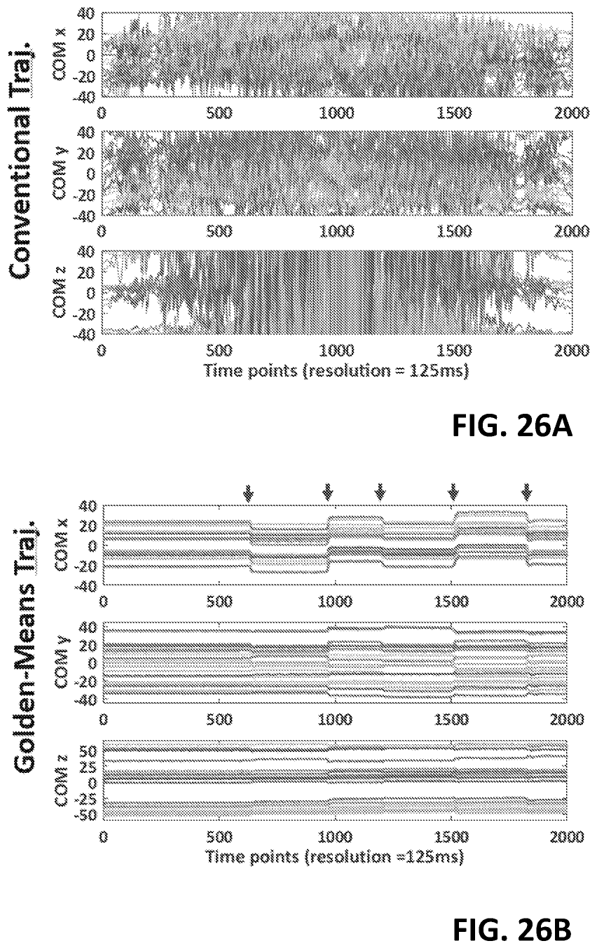

FIG. 26A shows an exemplary conventional trajectory. FIG. 26B shows an exemplary golden-means trajectory.

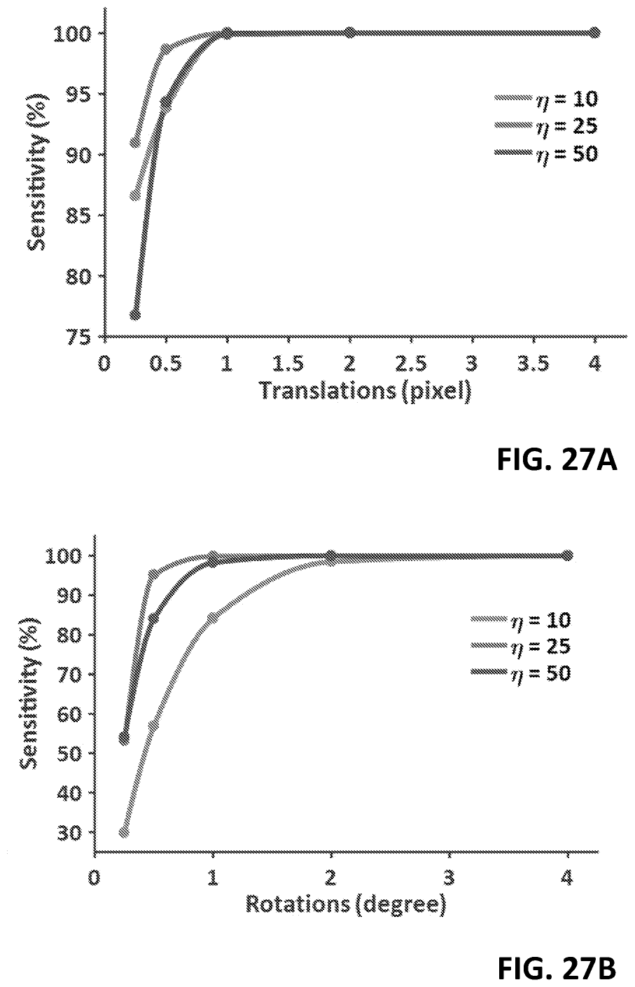

FIG. 27A shows exemplary translations and sensitivity. FIG. 27B shows exemplary rotations and sensitivity.

Sensitivity of COM-based motion detection is shown, including simulations with varying η (number of views for deriving a single COM value). Near-perfect detection capability for translations ≥1 pixel and rotations ≥1 degree.

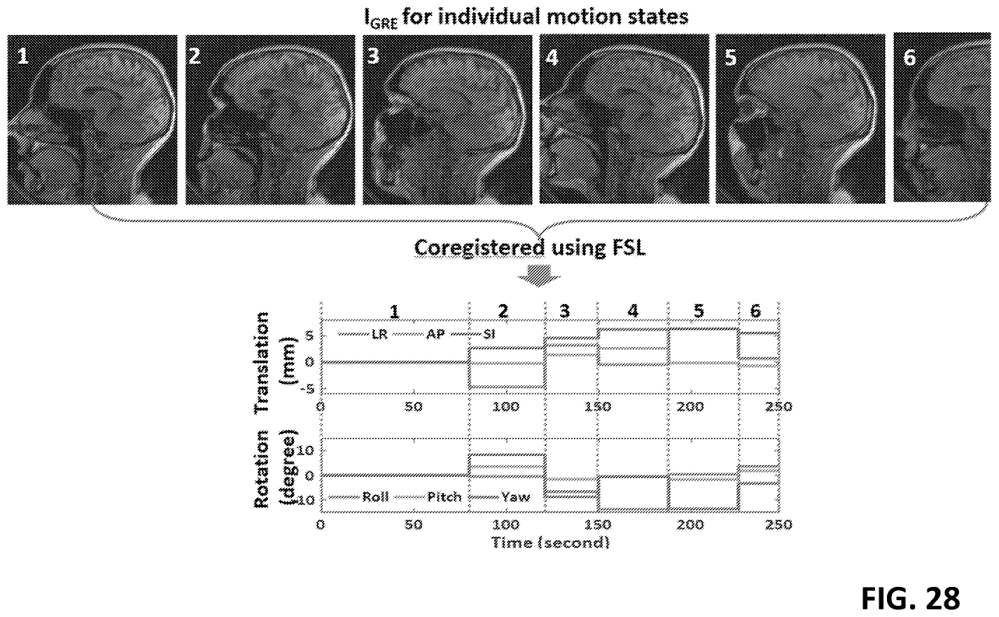

FIG. 28 shows exemplary motion estimation.

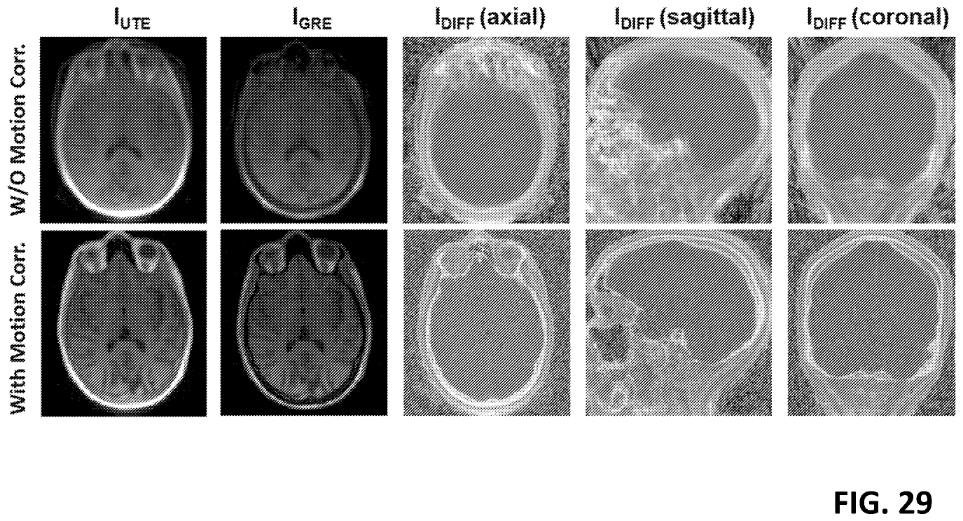

FIG. 29 shows exemplary motion correction. Applying the derived motion parameters to k-space data: rotation→rotation, translation→linear phase.

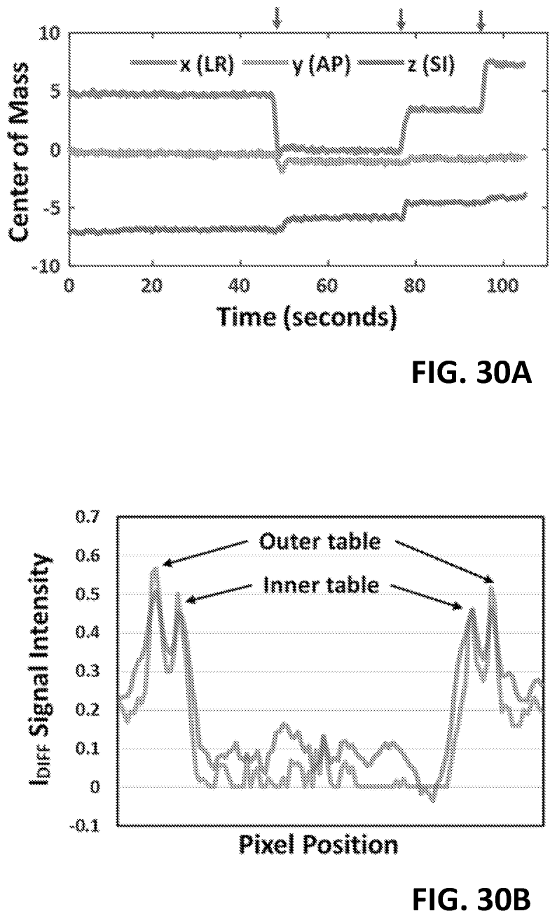

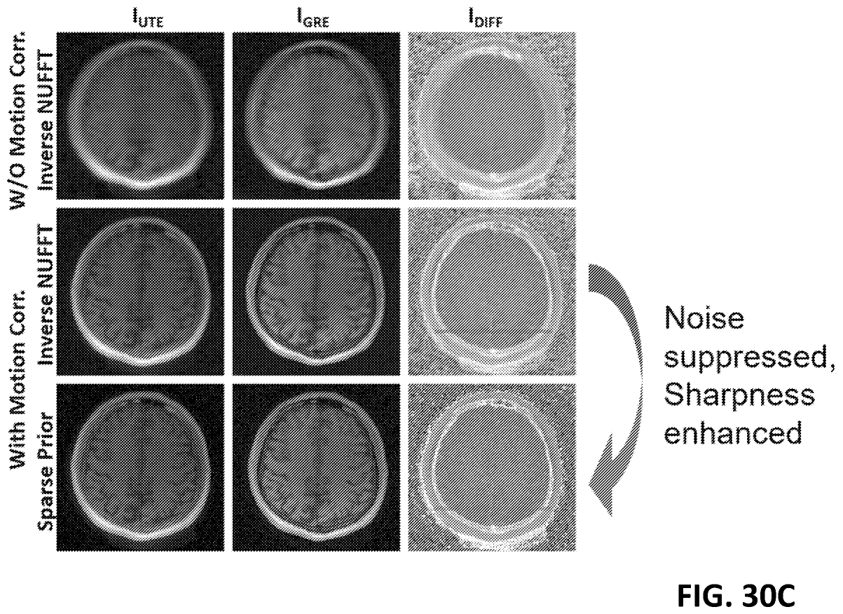

FIG. 30A-C shows motion correction and acceleration. Data acquisition: 21000 views in 110 s. Image reconstruction: using equation 2. FIG. 30A shows center of mass. FIG. 30B shows signal intensity. FIG. 30C shows a comparison of images.

As shown, a variety of aspects are provided, including self-navigation and a high temporal resolution COM extraction. Also provided is full echo acquisition for GRE signals. The disclosed technology also enables adaptive selection of subsets. Golden-means for uniform distribution of views within any time windows can be used. The disclosed technology also stabilizes the COM problem (as opposed to conventional view-ordering), and also provides quality images.

Also as shown, bone voxel conspicuity was substantially improved with motion correction and sparsity-constrained reconstruction.

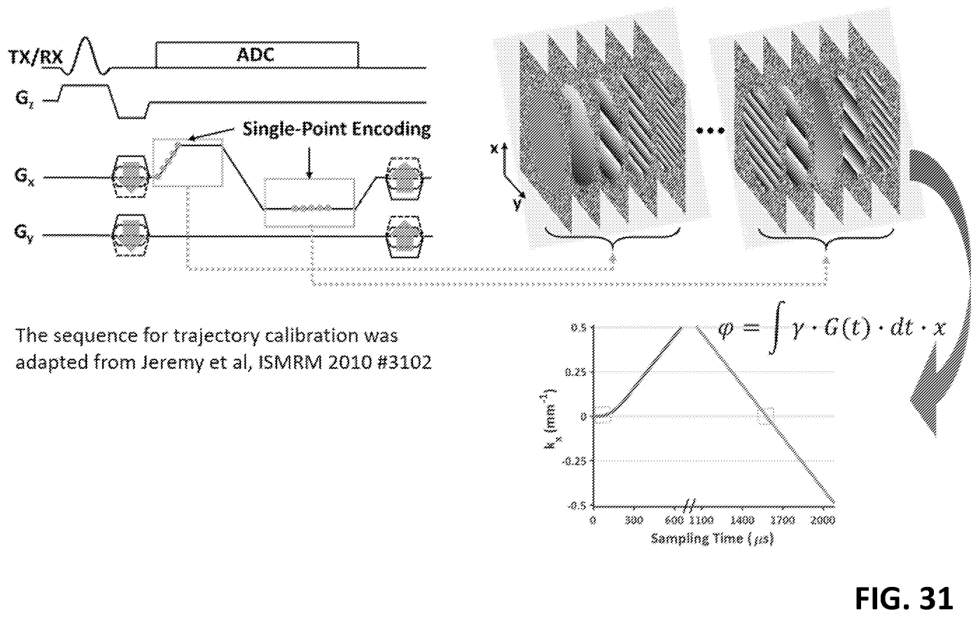

FIG. 31 shows trajectory calibration.

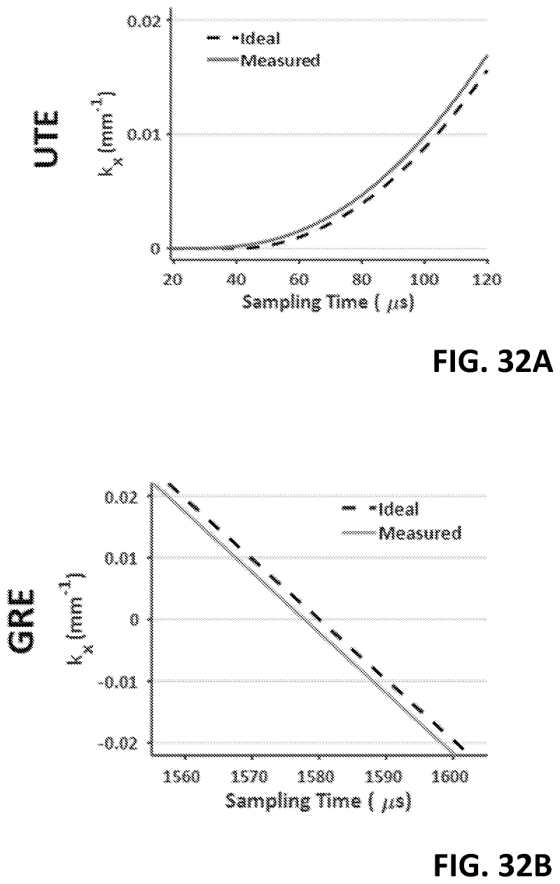

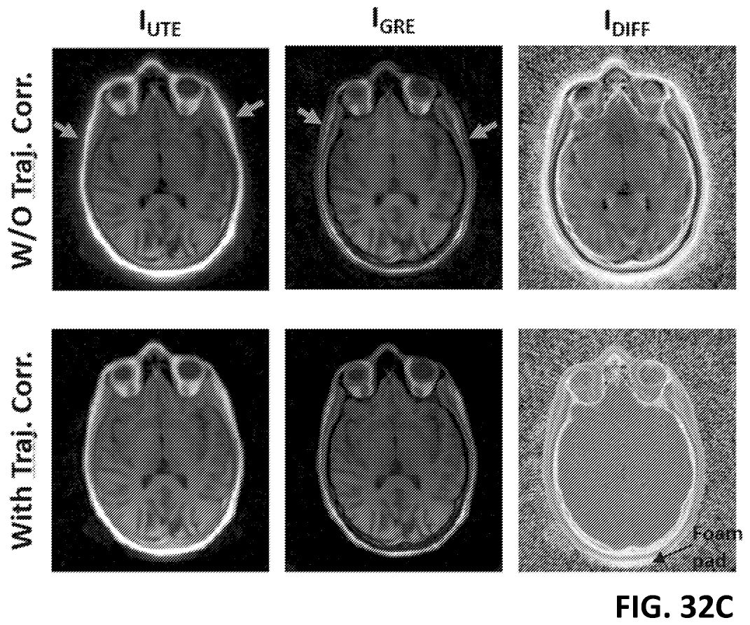

FIG. 32A-C shows trajectory correction. FIG. 32A shows UTE. FIG. 32B shows GRE. FIG. 32C shows a comparison of exemplary images.

Exemplary Aspects

The following aspects are illustrative only and do not serve to limit the scope of the present disclosure or the appended claims.

Aspect 1. A method for imaging, the method comprising: receiving first imaging data (e.g., or a for set of imaging data) at two or more echo times taken with a first radiofrequency configuration; receiving second imaging data (e.g., or a second set of imaging data) at two or more echo times taken with a second radiofrequency configuration; generating, based on at least the first imaging data and the second imaging data, two or more k-space datasets; and generating, based on at least the two or more k-space datasets, one or more images, wherein the one or more images comprise different image contrast.

Aspect 2. The method of Aspect 1, wherein one or more of the first imaging data or the second imaging data is captured via solid-state MRI.

Aspect 3. The method of any one of Aspects 1-2, wherein the first radiofrequency configuration comprises a first pulse length and the second radio frequency configuration comprises a second pulse length different from the first pulse length.
7 Aspect 4. The method of any one of Aspects 1-3, wherein the two or more image datasets comprise different signal strength levels of bone signals.

Aspect 5. The method of any one of Aspects 1-4, wherein the two or more image datasets comprise nearly identical signal strengths of intra- and extra-cranial components. The term nearly identical as used herein means about 95% or greater similarity (e.g., about 95% to about 100%). The term about as used in the prior sentence means that 95% is an approximate amount that could vary by between 1 and 5 percentage points. For example, nearly identical could mean 90% or greater, 91% or greater, 92% or greater, 93% or greater, 94% or greater, 95% or greater, 96% or greater, 97% or greater, 98% or greater, or 99% or greater.

Aspect 6. The method of any one of Aspects 1-5, wherein generating the one or more images comprises determining a temporal derivative based on different echo times, and normalizing the derivative by temporal integration.

Aspect 7. The method of any one of Aspects 1-6, wherein generating the one or more images comprises sparsity-constrained image reconstruction.

Aspect 8. The method of Aspect 7, wherein the sparsity-constrained image reconstruction is based on a function comprising a non-uniform Fourier transformation.

Aspect 9. A system comprising a solid-state MRI device and a computing device, wherein the computing device is configured to implement the method of any one of Aspects 1 and 3-8.

Aspect 10. A apparatus comprising computer-readable instructions and a processor configured to execute the computer-readable instructions to implement the method of any one of Aspects 1-8.

Aspect 11. A method for imaging, the method comprising: receiving, via a solid-state MRI, first imaging data associated with a first echo time and a first radio frequency configuration; receiving, via the solid-state MRI, second imaging data associated with a second echo time and a second radio frequency configuration different from the first echo time and the first radio frequency configuration, respectively; generating, based on at least the first imaging data and the second imaging data, two or more k-space datasets, wherein the two or more k-space datasets comprise different signal strength levels of bone signals and nearly identical signal strengths of intra- and extra-cranial components; and generating, based on at least the two or more k-space datasets, one or more images, wherein the one or more images comprise an image contrast between bone and soft tissue.

Aspect 12. The method of Aspect 11, wherein the first imaging data and the second imaging data is associated with a portion of a body.

Aspect 13. The method of any one of Aspects 11-12, wherein the first radio frequency configuration comprises a first pulse length and the second radio frequency configuration comprises a second pulse length different from the first pulse length.

Aspect 14. The method of any one of Aspects 11-13, wherein generating the one or more images comprises determining a temporal derivative based on different echo times, and normalizing the derivative by temporal integration to remove voxel-specific constants.

Aspect 15. The method of any one of Aspects 11-14, wherein generating the one or more images comprises sparsity-constrained image reconstruction.

Aspect 16. The method of Aspect 15, wherein the sparsity-constrained image reconstruction is based on a function comprising a non-uniform Fourier transformation.

Aspect 17. The method of any one of Aspects 11-16, further comprising outputting the one or more images to a human-readable medium.

Aspect 18. A system comprising the solid-state MRI device and a computing device, wherein the computing device is configured to implement the method of any one of Aspects 11-17.

Aspect 19. An apparatus comprising computer-readable instructions and a processor configured to execute the computer-readable instructions to implement the method of any one of Aspects 11-17.

Aspect 20. A method for imaging, the method comprising: receiving first imaging data of an object of interest at two or more echo times taken with a first radiofrequency configuration; determining, based on the first imaging data, a center of mass of the object of interest; determining, based on the first imaging data and the center of mass, a plurality of motion states of the object of interest; determining, based on at least a portion of the plurality of motion states, one or more motion correction parameters; correcting, based on the one or more motion correction parameters, two or more k-space datasets; and outputting, based on the corrected k-space datasets, one or more corrected images (e.g., motion corrected images).

Aspect 21. The method of Aspect 20, further comprising: receiving second imaging data at two or more echo times taken with a second radiofrequency configuration; and generating, based on at least the first imaging data and the second imaging data, the two or more k-space datasets.

Aspect 22. The method of Aspect 21, further comprising generating, based on at least a portion of the two or more k-space datasets, the one or more corrected images (e.g., motion corrected images), wherein the one or more images comprise different image contrast.

Aspect 23. The method of any one of Aspects 21-22, wherein receiving the first imaging data of an object of interest at two or more echo times taken with a first radiofrequency configuration comprises receiving gradient echo data based on a two-dimensional golden-means trajectory.

Aspect 24. The method of Aspect 23, wherein determining, based on the first imaging data and the center of mass, the plurality of motion states of the object of interest comprising determining, based on a time-course of the center of mass, the plurality of motion states.

Aspect 25. The method of any one of Aspects 20-24, wherein the one or more corrected images (e.g., motion corrected images) comprise an image contrast between bone and soft tissue.

Aspect 26. The method of any one of Aspects 20-25, wherein determining, based on at least the portion of the plurality of motion states, the one or more motion correction parameters comprises determining a motion trajectory comprise the one or more correction parameters.

Aspect 27. A system comprising a solid-state MRI device and a computing device, wherein the computing device is configured to implement the method of any one of Aspects 20-26.

Aspect 28. An apparatus comprising computer-readable instructions and a processor configured to execute the computer-readable instructions to implement the method of any one of Aspects 20-26.

Those skilled in the art also will readily appreciate that many additional modifications are possible in the exemplary embodiment without materially departing from the novel teachings and advantages of the invention. Accordingly, any such modifications are intended to be included within the scope of this invention as defined by the following exemplary claims.

1. A method for imaging, the method comprising:
receiving first imaging data at two or more echo times taken with a first radio frequency configuration;
receiving second imaging data at two or more echo times taken with a second radio frequency configuration;
generating, based on at least the first imaging data and the second imaging data, two or more k-space datasets; and
generating, based on at least the two or more k-space datasets, one or more images, wherein the one or more images comprise different image contrast.

2. The method of claim 1, wherein one or more of the first imaging data or the second imaging data is captured via solid-state MRI.

3. The method of claim 1, wherein the first radio frequency configuration comprises a first pulse length and the second radio frequency configuration comprises a second pulse length different from the first pulse length.

4. The method of claim 1, wherein the two or more image datasets comprise different signal strength levels of bone signals.

5. The method of claim 1, wherein the two or more image datasets comprise nearly identical signal strengths of intra- and extra-cranial components.

6. The method of claim 1, wherein generating the one or more images comprises determining a temporal derivative based on different echo times, and normalizing the derivative by temporal integration.

7. The method of claim 1, wherein generating the one or more images comprises sparsity-constrained image reconstruction.

8. The method of claim 7, wherein the sparsity-constrained image reconstruction is based on a function comprising a non-uniform Fourier transformation.

9-10. (canceled)

11. A method for imaging, the method comprising:
receiving, via a solid-state MRI, first imaging data associated with a first echo time and a first radio frequency configuration;
receiving, via the solid-state MRI, second imaging data associated with a second echo time and a second radio frequency configuration different from the first echo time and the first radio frequency configuration, respectively;
generating, based on at least the first imaging data and the second imaging data, two or more k-space datasets, wherein the two or more k-space datasets comprise different signal strength levels of bone signals and nearly identical signal strengths of intra- and extra-cranial components; and
generating, based on at least the two or more k-space datasets, one or more images, wherein the one or more images comprise an image contrast between bone and soft tissue.

12. The method of claim 11, wherein the first imaging data and the second imaging data is associated with a portion of a body.

13. The method of claim 11, wherein the first radio frequency configuration comprises a first pulse length and the second radio frequency configuration comprises a second pulse length different from the first pulse length.

14. The method of claim 11, wherein generating the one or more images comprises determining a temporal derivative based on different echo times, and normalizing the derivative by temporal integration to remove voxel-specific constants.

15. The method of claim 11, wherein generating the one or more images comprises sparsity-constrained image reconstruction.

16. The method of claim 15, wherein the sparsity-constrained image reconstruction is based on a function comprising a non-uniform Fourier transformation.

17. The method of claim 11, further comprising outputting the one or more images to a human-readable medium.

18-19. (canceled)

20. A method for imaging, the method comprising:
receiving first imaging data of an object of interest at two or more echo times taken with a first radio frequency configuration;
determining, based on the first imaging data, a center of mass of the object of interest;
determining, based on the first imaging data and the center of mass, a plurality of motion states of the object of interest;
determining, based on at least a portion of the plurality of motion states, one or more motion correction parameters;
correcting, based on the one or more motion correction parameters, two or more k-space datasets; and
outputting, based on the corrected k-space datasets, one or more corrected images.

21. The method of claim 20, further comprising:
receiving second imaging data at two or more echo times taken with a second radio frequency configuration; and
generating, based on at least the first imaging data and the second imaging data, the two or more k-space datasets.

22. The method of claim 21, further comprising generating, based on at least a portion of the two or more k-space datasets, the one or more corrected images, wherein the one or more corrected images comprise different image contrast.

23. The method of claim 21, wherein receiving the first imaging data of an object of interest at two or more echo times taken with a first radio frequency configuration comprises receiving gradient echo data based on a two-dimensional golden-means trajectory.

24. The method of claim 23, wherein determining, based on the first imaging data and the center of mass, the plurality of motion states of the object of interest comprising determining, based on a time-course of the center of mass, the plurality of motion states.

25-28. (canceled)
